(19) United States
(12) Patent Application Publication
(10) Pub. No.: US 2025/0372528 A1
(43) Pub. Date: Dec. 4, 2025

(54) ELECTRONIC DEVICE

(71) Applicant: InnoLux Corporation, Miao-Li County (TW)

(72) Inventors: Chandra LIUS, Miao-Li County (TW); Jui-Jen Yueh, Miao-Li County (TW); Kuan-Feng Lee, Miao-Li County (TW)

(73) Assignee: InnoLux Corporation, Miao-Li County (TW)

(21) Appl. No.: 19/189,181

(22) Filed: Apr. 24, 2025

(30) Foreign Application Priority Data
May 28, 2024 (CN) 202410668229.6

(51) Int. Cl. H01L 23/538; H01L 23/14; H01L 23/367; H01L 25/03

(52) U.S. Cl. CPC H01L 23/5386; H01L 23/147; H01L 23/3675; H01L 23/5385; H01L 25/03

(57) ABSTRACT

An electronic device includes a substrate, a first interposer and a plurality of package units. The first interposer is disposed on the substrate. The plurality of package units are disposed on the first interposer. Along a vertical direction, one of the plurality of package units sequentially includes a circuit structure, a first chip and a plurality of second chips. The circuit structure is disposed on the first interposer and electrically connected to the first interposer. The first chip is disposed on the circuit structure and electrically connected to the circuit structure. The plurality of second chips are disposed on the first chip and electrically connected to the circuit structure. The first chip overlaps at least two of the plurality of second chips, and the plurality of package units are electrically connected to the substrate through the first interposer.

### BACKGROUND OF THE DISCLOSURE

### 1. Field of the Disclosure

The present disclosure relates to an electronic device, and more particularly, to an electronic device using an integrated fan-out package-on-package (INFO POP) technology, a fan-out wafer-level package (FOWLP) technology or a fan-out panel-level package (FOPLP) technology.

### 2. Description of the Prior Art

In recent years, electronic devices are gradually miniaturized. Therefore, how to increase the maximum applied rate of planar space, so to enhance the arrangement density of electronic elements in electronic products and meet the trend of miniaturization of electronic products, has become a goal of manufacturers of electronic devices.

### SUMMARY OF THE DISCLOSURE

According to an embodiment of the present disclosure, an electronic device includes a substrate, a first interposer and a plurality of package units. The first interposer is disposed on the substrate. The plurality of package units are disposed on the first interposer. Along a vertical direction, one of the plurality of package units sequentially includes a circuit structure, a first chip and a plurality of second chips. The circuit structure is disposed on the first interposer and electrically connected to the first interposer. The first chip is disposed on the circuit structure and electrically connected to the circuit structure. The plurality of second chips are disposed on the first chip and electrically connected to the circuit structure. The first chip overlaps at least two of the plurality of second chips, and the plurality of package units are electrically connected to the substrate through the first interposer.

According to another embodiment of the present disclosure, an electronic device includes at least two package units, a first interposer and a plurality third of chips. The at least two package units are disposed adjacent to each other. Along a vertical direction, any one of the at least two package units sequentially includes a circuit structure, a first chip and a second chip. The first chip is disposed on the circuit structure and electrically connected to the circuit structure. The second chip is disposed on the first chip and electrically connected to the circuit structure. The first interposer is disposed on the at least two package units and electrically connected to the at least two package units. The plurality of third chips are disposed on the first interposer and electrically connected to the first interposer.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic cross-sectional view showing an electronic device according to an embodiment of the present disclosure.

FIG. 2 is an enlarged view of part A in FIG. 1.

FIG. 3 is an enlarged view of part B in FIG. 1.

FIG. 4 is an enlarged view of part C in FIG. 1.

FIG. 5 is a schematic cross-sectional view showing an electronic device according to another embodiment of the present disclosure.

FIG. 6 is an enlarged view of part D in FIG. 5.

FIG. 7 is an enlarged view of part E in FIG. 5.

FIG. 8 is a schematic cross-sectional view showing an electronic device according to yet another embodiment of the present disclosure.

FIG. 9 is a schematic cross-sectional view showing an electronic device according to yet another embodiment of the present disclosure.

FIG. 10 is a schematic cross-sectional view showing an electronic device according to yet another embodiment of the present disclosure.

FIG. 11 is a schematic cross-sectional view showing an electronic device according to yet another embodiment of the present disclosure.

FIG. 12 is a schematic cross-sectional view showing an electronic device according to yet another embodiment of the present disclosure.

FIG. 13 is a schematic cross-sectional view showing an electronic device according to yet another embodiment of the present disclosure.

FIG. 14 is a schematic cross-sectional view showing an electronic device according to yet another embodiment of the present disclosure.

FIG. 15 is a schematic cross-sectional view showing an electronic device according to yet another embodiment of the present disclosure.

FIG. 16 is a schematic cross-sectional view showing an electronic device according to yet another embodiment of the present disclosure.

FIG. 17 is a schematic cross-sectional view showing an electronic device according to yet another embodiment of the present disclosure.

FIG. 18 is a schematic cross-sectional view showing an electronic device according to yet another embodiment of the present disclosure.

### DETAILED DESCRIPTION

The present disclosure may be understood by reference to the following detailed description, taken in conjunction with the drawings as described below. Wherever possible, the same or similar parts in the drawings and descriptions are represented by the same reference numeral.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include/comprise” and “have” are used in an open-ended fashion, and thus should be interpreted to mean “include, but not limited to . . . ”.

In the present disclosure, the directional terms, such as “on/up/above”, “down/below”, “front”, “rear/back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

In the present disclosure, when a structure (or layer, or component, or substrate) is described as located on/above another structure (or layer, or component, or substrate), it may refer that the two structures are adjacent and directly connected to each other, or the two structures are adjacent and indirectly connected to each other. The two structures being indirectly connected to each other may refer that at least one intervening structure (or intervening layer, or intervening component, or intervening substrate, or intervening interval) exists between the two structures, a lower surface of one of the two structure is adjacent or directly connected to an upper surface of the intervening structure, and an upper surface of the other of the two structures is adjacent or directly connected to a lower surface of the intervening structure. The intervening structure may be a single-layer or multi-layer physical structure or a non-physical structure, and the present disclosure is not limited thereto. In the present disclosure, when a certain structure is disposed “on/above” other structures, it may refer that the certain structure is “directly” disposed on/above the other structures, or the certain structure is “indirectly” disposed on/above the other structures, i.e., at least one structure is disposed between the certain structure and the other structures.

The terms “equal”, “identical/the same”, or “substantially/approximately” mentioned in this document generally mean being within 20% of a given value or range, or being within 10%, 5%, 3%, 2%, 1% or 0.5% of the given value of range.

Furthermore, any two values or directions used for comparison may have a certain error. If a first value is equal to a second value, it implies that there may be an error of about 10% between the first value and the second value; if a first direction is perpendicular or “substantially” perpendicular to a second direction, then an angle between the first direction and the second direction may be between 80 degrees to 100 degrees; if the first direction is parallel or “substantially” parallel to the second direction, an angle between the first direction and the second direction may be between 0 degree to 10 degrees.

Although ordinal numbers such as “first”, “second”, etc., may be used to describe elements in the description and the claims, it does not imply and represent that there have other previous ordinal number. The ordinal numbers do not represent the order of the elements or the manufacturing order of the elements. The ordinal numbers are only used for discriminate an element with a certain designation from another element with the same designation. The claims and the description may not use the same terms. Accordingly, a first element in the description may be a second element in the claims.

In addition, the term “a given range is from a first value to the second value” or “a given range falls within a range from a first value to a second value” refers that the given range includes the first value, the second value and other values therebetween.

Moreover, the electronic device of the present disclosure may include or be applied to an AI server, a cloud server, an edge computing server, vehicle-mounted electronics, Internet of Thing (IOT), and Intelligent Internet of Thing (AIOT), a display device, a backlight device, an antenna device, a sensing device, a tiled device, a touch display device, a curved display device or a free shape display device, but not limited thereto. The display device may be a non-self-luminous type display device or a self-luminous type display device. The antenna device may be a liquid-crystal-type antenna device or a non-liquid-crystal-type antenna device. The sensing device may be a device for sensing capacitance, light, thermal or ultrasonic, but not limited thereto. The electronic elements of the electronic device may include passive elements and active elements, such as capacitors, resistors, inductors, diodes, transistors, etc. The diode may include a light emitting diode (LED) or a photodiode. The light emitting diode may include organic light emitting diode (OLED), mini LED, micro LED or quantum dot LED, but not limited thereto. The tiled device may exemplarily be a tiled display device or a tiled antenna device, but not limited thereto. Furthermore, the electronic devices may be foldable or flexible electronic devices. The electronic device may be any combination of aforementioned devices, but not limited thereto. Furthermore, a shape of the electronic device may be a rectangle, a circle, a polygon, a shape with curved edge or other suitable shapes. The electronic device may have peripheral systems, such as a driving system, a control system, a light system, etc., for supporting the display device, the antenna device, the wearable device (for example, including augmented reality (AR) device or virtual reality (VR) device), the vehicle-mounted device (for example, including car windshields) or the tiled device.

In the present disclosure, it should be understood that a depth, a thickness, a width or a height of each element, or a space or a distance between elements may be measured by an optical microscopy (OM), a scanning electron microscope (SEM), a film thickness profiler (α-step), an ellipsometer or r other suitable methods. In some embodiments, a cross-sectional image including elements to be measured can be obtained by the SEM, and the depth, the thickness, the width or the height of each element, or the space or the distance between elements can be measured thereby.

It should be noted that the technical features in different embodiments described in the following can be replaced, recombined, or mixed with one another to constitute another embodiment without departing from the spirit of the present disclosure.

Unless otherwise defined, all terms (including technical and scientific terms) used herein have the same meaning as commonly understood by a person having ordinary skill in the art to which the disclosure belongs. It can be understood that these terms, such as those defined in commonly used dictionaries, should be interpreted as having meanings consistent with the background or context of the related technology and the present disclosure, and should not be interpreted in an idealized or overly formal manner, unless otherwise specified in the disclosed embodiments.

In the present disclosure, when an element is disposed on a surface of another element, it may refer that the element is disposed on the surface of the another element or the element is embedded in the surface of the another element.

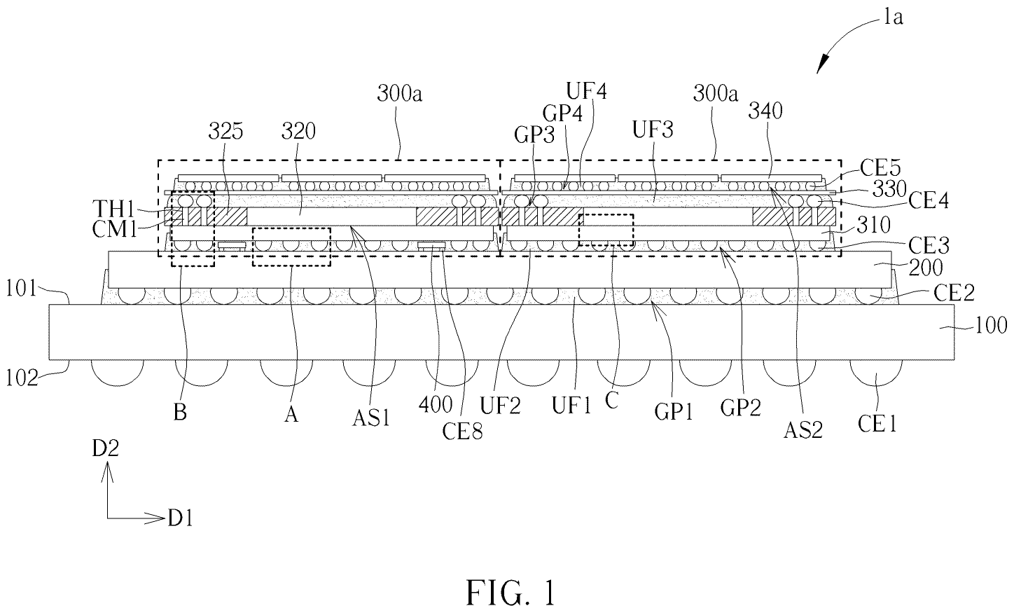

Please refer to FIG. 1, which is a schematic cross-sectional view showing an electronic device 1a according to an embodiment of the present disclosure. The electronic device 1a includes a substrate 100, an interposer 200 and a plurality of package units 300a. The interposer 200 is disposed on the substrate 100, and the plurality of package units 300a are disposed on the interposer 200. Each of the package units 300a sequentially includes a circuit structure 310, a chip 320 and a plurality of chips 340 along a vertical direction D2. In a single package unit 300a, the circuit structure 310 is disposed on the interposer 200 and electrically connected to the interposer 200. The chip 320 is disposed on the circuit structure 310 and electrically connected to the circuit structure 310. The circuit structure 310 may be, for example (but not limited to) a redistribution layer (RDL) structure; the plurality of chips 340 are disposed on the chip 320 and electrically connected to the circuit structure 310; the chip 320 overlaps at least two of the plurality of chips 340. Furthermore, the plurality of package units 300a are electrically connected to the substrate 100 through the interposer 200. Thereby, each of the package units 300a includes at least two types of chips (such as the chip 320 and the chip 340) stacked along the vertical direction D2, which is beneficial to increase the maximum applied rate of planar space, so that the arrangement of the electronic elements in the electronic device 1a can be denser, and the current trend of miniaturization of electronic products can be satisfied.

The aforementioned “the chip 320 overlaps at least two of the plurality of chips 340” may refer that the chip 320 partially overlaps or completely overlaps the at least two chips 340 in one direction, and the aforementioned direction is exemplarily the vertical direction D2. The vertical direction D2 may be, for example, parallel to a normal direction (not shown) of the top surface 101 of the substrate 100.

Specifically, the package unit 300a may be an integrated fan-out package unit, and the package unit 300a is disposed on the substrate 100 and the interposer 200 to form a structure of chip on wafer on substrate (CoWoS). In other words, the electronic device 1a may be a framework of CoWoS. The chip 320 may be, for example, a system on chip (SoC), a co-packaged optics (CPO) chip, or an application-specific integrated circuit (ASIC) chip, but not limited thereto. The chip 340 may be, for example, a system on chip (SoC), a dynamic random-access memory (DRAM) chip, a high bandwidth memory (HBM) chip, a photonic integrated circuit (PIC) chip, an application-specific integrated circuit (ASIC) chip, or other logic integrated circuit chips, but not limited thereto. According to an embodiment of the present disclosure, the chip 320 and the chip 340 may be unpackaged chips, but not limited thereto.

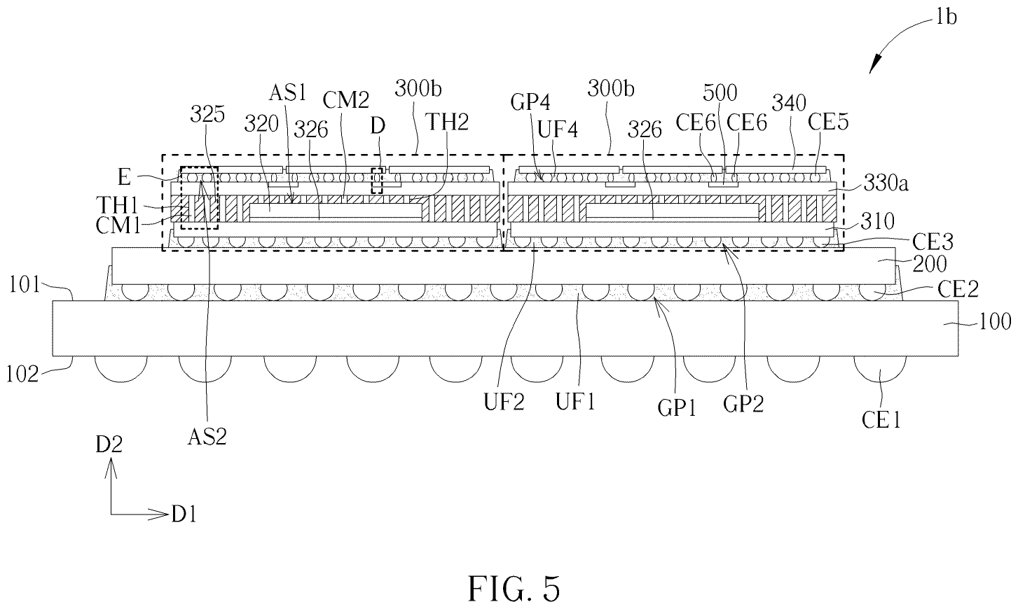

In the embodiment, the electronic device 1a may optionally further include one or more passive elements 400. The passive element 400 is disposed on the interposer 200 and electrically connected to the interposer 200. Herein, the number of the passive elements 400 is two, and the passive elements 400 are disposed between one of the package units 300a and the interposer 200, but not disposed between the other one of the package units 300a and the interposer 200. However, the present disclosure is not limited thereto. The number and the disposed positions of the passive elements 400 may be adjusted according to actual needs. In some embodiments, the passive elements 400 may be disposed between the two package units 300a and the interposer 200, and the number of the passive elements 400 disposed between one of the package units 300a and the interposer 200 may be the same as or different from the number of the passive elements 400 disposed between the other one of the package units 300a and the interposer 200. Alternatively, the electronic device 1a may not include the passive elements 400 disposed between the package units 300a and the interposer 200. In addition, when there are a plurality of passive elements 400, the types of the plurality of passive elements 400 may be independently the same or different. The passive element 400 may be, for example, a resistor, a capacitor or an inductor, but not limited thereto. In addition, although the passive element 400 is not shown in the electronic devices 1b, 1c, 1d, 1e, 1f, 1g, 1h, 1i, 1j, 1k, 1l and 1m in FIG. 5 and FIG. 8 to FIG. 18 below, the electronic devices 1b, 1c, 1d, 1e, 1f, 1g, 1h, 1i, 1j, 1k, 1l and 1m may be independently disposed with the passive element 400 according to actual needs. Details about the passive element 400 are omitted below.

In the embodiment, the total number of package units 300a is two. There is one chip 320 and three chips 340 in each of the package units 300a. However, it is only exemplary, and the number of package units 300a and the number of the chips 320 and 340 in each of the package units 300a may be adjusted according to actual needs. In this embodiment, the structures of the plurality of package units 300a are exemplarily the same, but not limited thereto. The structures of the plurality of package units 300a may be independently the same or different. The numbers and the types of the chips 320 and the chips 340 in different package units 300a may be independently the same or different.

In the embodiment, the two package units 300a are arranged side by side along the horizontal direction D1. The aforementioned horizontal direction D1 may be, for example, perpendicular to the normal direction (not shown) of the top surface 101 of the substrate 100, and the horizontal direction D1 and the vertical direction D2 may be perpendicular to each other. The aforementioned “the two package units 300a being arranged side by side along the horizontal direction D1” may refer that the two package units 300a do not overlap with each other in the vertical direction D2.

The package unit 300a may further include an interposer 330. The interposer 330 is disposed between the chip 320 and the plurality of chips 340 along the vertical direction D2, and can be electrically connected to the chip 320 and the plurality of chips 340.

The electronic device 1a may further include a plurality of bonding elements CE1, a plurality of bonding elements CE2, a plurality of bonding elements CE3, a plurality of bonding elements CE4, a plurality of bonding elements CE5 and a plurality of bonding elements CE8. The bonding elements CE1, CE2, CE3, CE4, CE5 and CE8 may be made of conductive materials and thus can provide conductive functions. The aforementioned conductive materials may include metals, such as tin, tin-silver alloy, tin-silver-bismuth alloy, tin-gold alloy, tin-nickel-gold alloy, nickel-gold alloy, other suitable materials or a combination thereof, but not limited thereto. The conductive materials of the plurality of bonding elements CE1, CE2, CE3, CE4, CE5 and CE8 may be independently the same or different. The plurality of bonding elements CE1, CE2, CE3, CE4, CE5 and CE8 may independently be, for example, bumps, solder balls or pads, but not limited thereto.

The plurality of bonding elements CEL are disposed on a bottom surface 102 of the substrate 100. The substrate 100 can be electrically connected to other external elements (not shown) through the bonding elements CE1. The plurality of bonding elements CE2 are disposed between the substrate 100 and the interposer 200. The substrate 100 and the interposer 200 can be electrically connected through the plurality of bonding elements CE2. The plurality of bonding elements CE3 are disposed between the interposer 200 and the circuit structure 310. The interposer 200 and the circuit structure 310 can be electrically connected through the plurality of bonding elements CE3. The plurality of bonding elements CE4 are disposed between the circuit structure 310 and the interposer 330. The circuit structure 310 and the interposer 330 can be electrically connected through the plurality of bonding elements CE4. The plurality of bonding elements CE5 are disposed between the interposer 330 and the chips 340. The interposer 330 and the chips 340 can be electrically connected through the plurality of bonding elements CE5. The plurality of bonding elements CE8 are disposed between the interposer 200 and the passive elements 400. The interposer 200 and the passive elements 400 can be electrically connected through the plurality of bonding elements CE8.

According to an embodiment of the present disclosure, the size of the bonding element CE5 is smaller than the size of the bonding element CE3, and the size of the bonding element CE3 is smaller than the size of the bonding element CE1. The aforementioned “size” may refer to the maximum length of each of the bonding elements CE1, CE3 and CE5 in one direction. For example, when the bonding element CE1 is formed in a spherical shape, the size of the bonding element CE1 is the diameter of the spherical shape. According to an embodiment of the present disclosure, the size of the bonding element CE1 is greater than or equal to 150 micrometers (μm) and less than or equal to 750 μm, the size of the bonding element CE3 is greater than or equal to 50 μm and less than or equal to 150 μm, the size of the bonding element CE5 is greater than or equal to 1 μm and less than or equal to 50 μm, but not limited thereto.

The electronic device 1a may optionally further include fillers UF1, UF2, UF3 and UF4. There are gaps GP1 existing between the plurality of bonding elements CE2, and the filler UF1 is disposed in the gaps GP1 between the plurality of bonding elements CE2. There are gaps GP2 existing between the plurality of bonding elements CE3 and CE8, and the filler UF2 is disposed in the gaps GP2 between the plurality of bonding elements CE3 and CE8. There are gaps GP3 existing between the plurality of bonding elements CE4, and the filler UF3 is disposed in the gaps GP3 between the plurality of bonding elements CE4. There are gaps GP4 existing between the plurality of bonding elements CE5, and the filler UF4 is disposed in the gaps GP4 between the plurality of bonding elements CE5. For example, the fillers UF1, UF2, UF3 and UF4 may be underfills. The fillers UF1, UF2, UF3 and UF4 may include acrylic, epoxy resin, resin, photoresist materials, other suitable materials, or a combination thereof, but not limited thereto. Furthermore, the fillers UF1, UF2, UF3 and UF4 may be independently the same or different. The fillers UF1, UF2, UF3 and UF4 can protect and fix the bonding elements CE2, CE3, CE4, CE5 and CE8, so that falling off caused by external forces or poor electrical connections can be reduced.

The substrate 100 may be, for example, a printed circuit board (PCB), a package substrate, or a substrate like PCB (SLP), but not limited thereto. Any carrier that can provide the function of electrical connection, such as a carrier including an insulating layer and a wire structure disposed therein and capable of providing the function of electrical connection, may be applied as the substrate 100 of the present disclosure. In an embodiment of the present disclosure, the substrate 100 includes a base, redistribution layer structures formed on an upper surface and a lower surface of the base, and a through hole penetrating the base. The base may include glass or silicon.

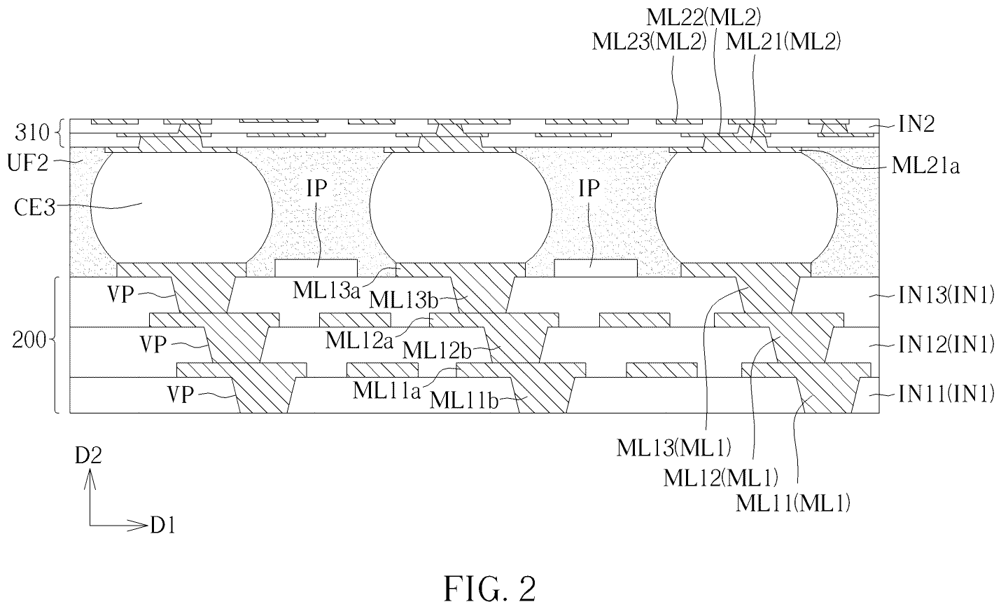

Please also refer to FIG. 2, which is an enlarged view of part A in FIG. 1. As shown in FIG. 2, the bonding element CE3 is exemplarily a metal bump, and the interposer 200 is exemplarily a redistribution layer (RDL) structure. The interposer 200 may include at least one insulating layer IN1 and at least one conductive layer ML1. In the embodiment, the interposer 200 includes a plurality of insulating layers IN1 and a plurality of conductive layers ML1, but not limited thereto. According to an embodiment of the present disclosure, the interposer 200 includes a base, conductive layers formed on an upper surface and a lower surface of the base, and a through hole penetrating the base. The base may include glass or silicon. Each of the insulating layers IN1 may be stacked sequentially along the vertical direction D2, and the interposer 200 can be electrically connected to the bonding element CE3 through the conductive layer ML1. For example, the interposer 200 may include at least three insulating layers IN1 and at least three conductive layers ML1, and each of the insulating layers IN1 may have a plurality of via holes VP. The three insulating layers IN1 are respectively insulating layers IN11, IN12 and IN13 from bottom to top, and the three conductive layers ML1 are respectively conductive layers ML11, ML12 and ML13 from bottom to top. The conductive layers ML1 may be formed in the insulating layers IN1 by the following method. For example, the insulating layer IN11 may be formed first, and then the via hole VP may be formed in the insulating layer IN11 through a photolithography and etching process. Next, a conductive layer (not shown) may be formed on the insulating layer IN11 and filled into the via hole VP, and then another photolithography and etching process may be performed to pattern the conductive layer to form the patterned conductive layer ML11a on the insulating layer IN11 and the via conductive layer ML11b in the via hole VP. Therefore, the conductive layer ML11 includes the patterned conductive layer ML11a and the via conductive layer ML11b. Similarly, the conductive layer ML12 includes a patterned conductive layer ML12a and a via conductive layer ML12b, and the conductive layer ML13 includes a patterned conductive layer ML13a and a via conductive layer ML13b. The patterned conductive layer ML13a located on the upper surface of the interposer 200 may serve as a conductive pad of the interposer 200 for external connection. That is, the patterned conductive layer ML13a may serve as an interface for the electrical connection between the interposer 200 and other elements (herein, the bonding elements CE3). The patterned conductive layer ML13a is electrically connected to the patterned conductive layer ML12a of the next layer through the via conductive layer ML13b. That is, the patterned conductive layer and the via conductive layer of the same layer (such as the patterned conductive layer ML13a and the via conductive layer ML13b) may together form a wire structure (not labeled). Therefore, the connection manner of the wire structure in the interposer 200 may be adjusted by adjusting the position of the via conductive layer, and thus the position of the patterned conductive layer ML13a of the interposer 200 for external connection can be flexibly adjusted. Accordingly, the purpose of wire redistribution can be achieved. The numbers of the insulating layers IN1 and the conductive layers ML1, the patterns of the conductive layers ML1, and the position of the via holes VP included in the interposer 200 are not limited by the above description.

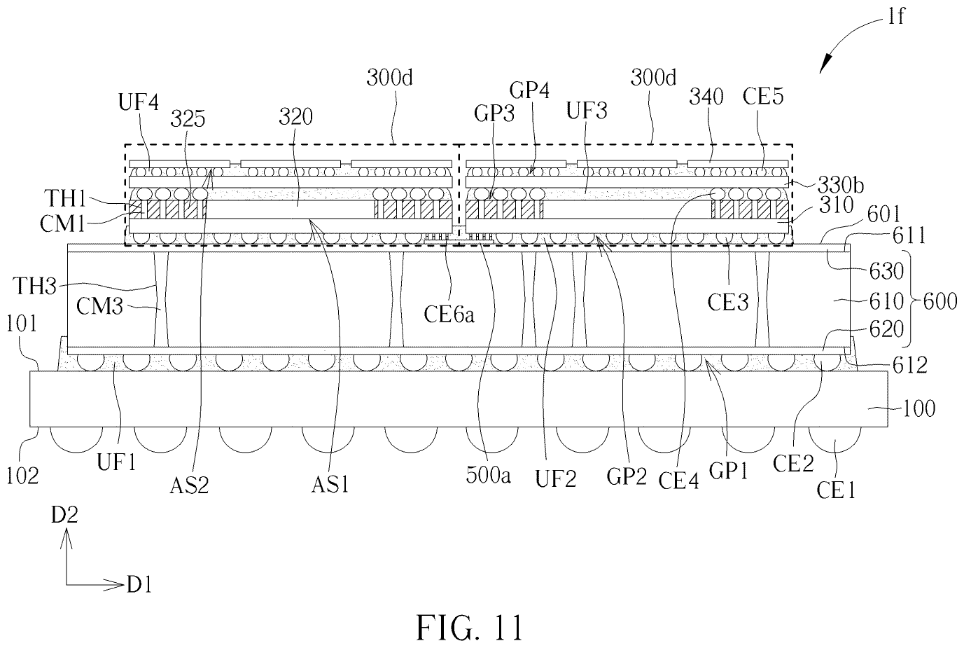

With the interposer 200 having the redistribution layer structure, the position of the patterned conductive layer ML13a of the interposer 200 for external connection can be flexibly adjusted according to actual needs. For example, the position of the patterned conductive layer ML13a may be adjusted to match the position of the bonding element CE3, so that the circuit design of the electronic device 1a is more flexible. However, the present disclosure is not limited thereto. Any film layer including an insulating layer and a wire structure disposed therein and capable of providing the function of electrical connection can be applied as the interposer 200 of the present disclosure. For this part, references may be made to the relevant descriptions of FIG. 11 to FIG. 13. With the redistribution layer structure, the wire of the electronic device 1a may be redistributed and the fan-out area of the wire may be further enhanced. Alternatively, different electronic elements can be electrically connected to each other through the redistribution layer structure. Alternatively, the redistribution layer structure can be configured to redistribute the sizes of the conductive pads that are fanned out or fanned in the chip. For example, the distance between two adjacent conductive pads at one end of the redistribution layer structure contacting the chip is smaller than the distance between two adjacent conductive pads at the other end of the redistribution layer structure away from the chip. For example, the center of the conductive pad at one end of the redistribution layer structure contacting the chip is offset relative to the center of the conductive pad at the other end of the redistribution layer structure away from the chip in the horizontal direction (such as the horizontal direction D1).

The interposer 200 may further include at least one insulating pattern IP disposed between two adjacent patterned conductive layers ML13a. Thereby, it can prevent the short circuit caused by the contact between two adjacent patterned conductive layers ML13a or two adjacent bonding elements CE3 when the electronic device 1a is squeezed by an external force.

Please still refer to FIG. 2. The circuit structure 310 is exemplarily a redistribution layer structure. The circuit structure 310 may include at least one insulating layer IN2 and at least one conductive layer ML2. For example, the conductive layer ML2 may sequentially include conductive layers ML21, ML22 and ML23 from bottom to top. The conductive layer ML2 is disposed in the insulating layer IN2. The circuit structure 310 can be electrically connected to the bonding elements CE3 through the conductive layer ML2. For details about the insulating layer IN2 and the conductive layer ML2, references may be made to the relevant descriptions of the insulating layer IN1 and the conductive layer ML1, and are omitted herein. The patterned conductive layer ML21a of the conductive layer ML2 disposed on the surface of the circuit structure 310 can serve as an interface for the electrical connection between the circuit structure 310 and other elements (herein, the bonding element CE3). With the circuit structure 310 having the redistribution layer structure, the position of the patterned conductive layer ML21a of the circuit structure 310 for external connection may be flexibly adjusted according to actual needs. For example, the position of the patterned conductive layer ML21a may be adjusted to match the position of the bonding element CE3, so that the circuit design of the electronic device 1a is more flexible. However, the present disclosure is not limited thereto. Any film layer including an insulating layer and a wire structure disposed therein and capable of providing the function of electrical connection can be applied as the circuit structure 310 of the present disclosure.

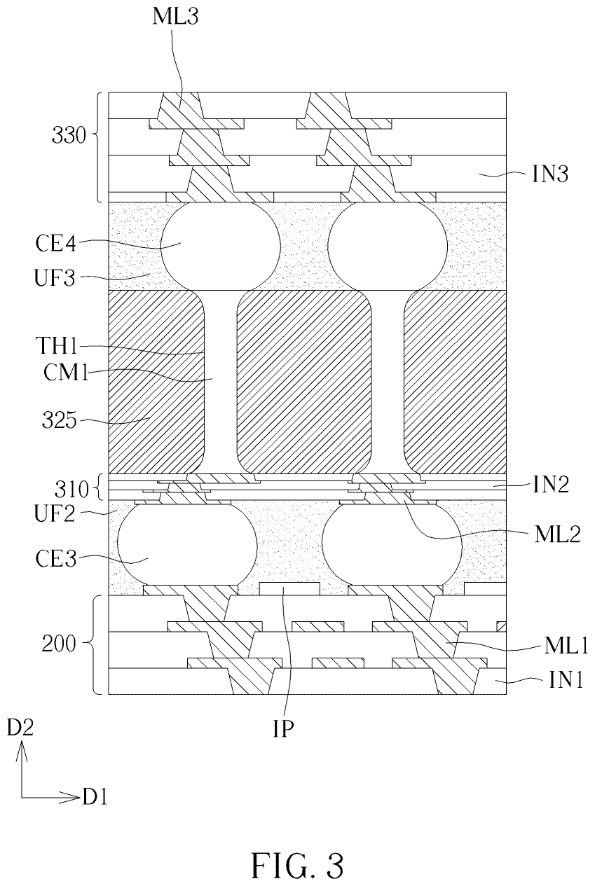

Please refer to FIG. 1 and FIG. 3 at the same time. FIG. 3 is an enlarged view of part B in FIG. 1. As shown in FIG. 1 and FIG. 3, the bonding element CE4 is exemplarily a metal bump. Each of the package unit 300a may further include a molding layer 325 surrounding and covering the side surfaces of the chip 320. At least one through hole TH1 is formed in the molding layer 325, and the through hole TH1 is filled with a conductive material to form a conductive element CM1. The conductive material, for example, may include copper, but not limited thereto. The conductive element CM1 can also be called a through insulator via (TIV) element or a through interlayer via element.

The interposer 330 is exemplarily a redistribution layer structure. The interposer 330 may include at least one insulating layer IN3 and at least one conductive layer ML3. The interposer 330 can be electrically connected to the bonding elements CE4 through the conductive layer ML3. For details about the insulating layer IN3 and the conductive layer ML3, references may be made to the relevant descriptions of the insulating layer IN1 and the conductive layer ML1, and are omitted herein. With the interposer 330 having the redistribution layer structure, the circuit design of the electronic device 1a can be more flexible. However, the present disclosure is not limited thereto. Any film layer including an insulating layer and a wire structure disposed therein and capable of providing the function of electrical connection can be applied as the interposer 330 of the present disclosure.

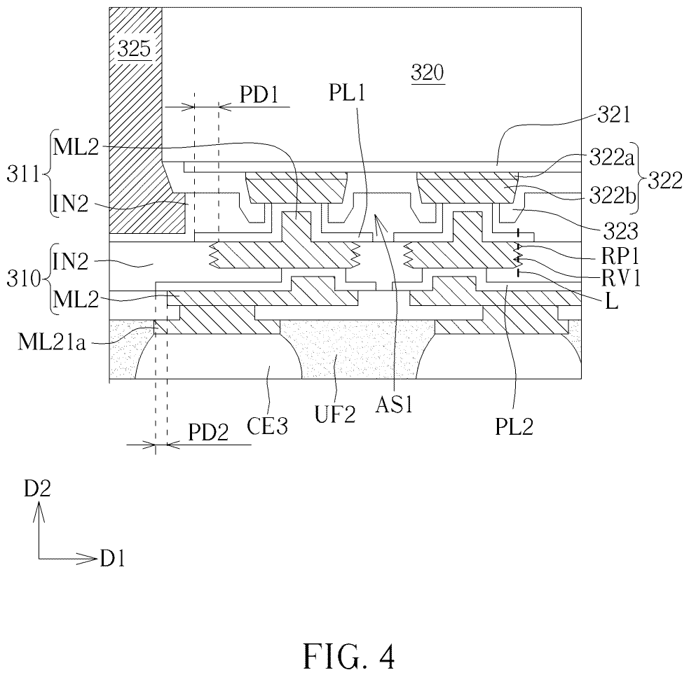

Please refer to FIG. 4, which is an enlarged view of part C in FIG. 1. Each of the package units 300a may further include a circuit layer 321, at least one conductive pad 322, and an insulating layer 323. The circuit layer 321 is disposed on a surface of the active side AS1 of the chip 320, and the conductive pad 322 is disposed on the surface of the circuit layer 321 and electrically connected to the circuit layer 321. In the embodiment, there are a plurality of conductive pads 322, and the conductive pads 322 are separated from each other, so that the conductive pads 322 can be applied to transmit different signals or form different electrical paths. The conductive pad 322 may also be called an under-bump metallization (UBM). The insulating layer 323 is disposed on the circuit layer 321 and the conductive pad 322, and the insulating layer 323 covers portions of the circuit layer 321 and the conductive pad 322, and exposes a portion of the conductive pad 322 for electrical connection with other elements. The insulating layer 323 is configured to provide the function of electrical insulation and prevent the functions of the circuit layer 321 and the conductive pad 322 form being affected by external objects such as moisture and/or dust. The conductive pad 322 may serve as an interface for electrical connection between the chip 320 and other elements (herein, the circuit structure 310). Herein, the conductive pad 322 exemplarily includes a double-layer structure including a bottom metal layer 322a and a top metal layer 322b. The bottom metal layer 322a is disposed on the circuit layer 321, and the top metal layer 322b is disposed on the bottom metal layer 322a. The material of the bottom metal layer 322a may include tantalum (Ta), but not limited thereto. The material of the top metal layer 322b may include iron, aluminum, copper, other suitable materials, or a combination thereof, but not limited thereto. According to an embodiment of the present disclosure, the material of the top metal layer 322b may include aluminum. In other embodiments of the present disclosure, the conductive pad 322 may be a single-layer structure or a multi-layer structure of three or more layers. The material of the insulating layer 323 may include silicon oxide (SiOx), silicon nitride (SiNx), other suitable materials, or a combination thereof, but not limited thereto.

As shown in FIG. 4, the circuit structure 310 may further include an extending portion 311 extending into the molding layer 325, i.e., being surrounded by the molding layer 325. The extending portion 311 may include at least one insulating layer IN2 and at least one conductive layer ML2. The conductive layer ML2 is disposed in the insulating layer IN2 and is electrically connected to the conductive pad 322. In other words, the circuit structure 310 is electrically connected to the chip 320 through the conductive pad 322 and the circuit layer 321.

Each of the package unit 300a may further include a first seed layer PL1 and a second seed layer PL2. The first seed layer PL1 is disposed between the conductive pad 322 and the conductive layer ML2 closest to the conductive pad 322. The side surface of the first seed layer PL1 protrudes from the side surface of the conductive layer ML2 closest to the conductive pad 322 by a first distance PD1. The first distance is greater than zero, which is beneficial to reduce the risk of peeling and improve the reliability of the electronic device 1a. Specifically, the adhesion between the first seed layer PL1 and the insulating layer IN2 is better than the adhesion between the conductive layer ML2 closest to the conductive pad 322 and the insulating layer IN2. If the side surface of the conductive layer ML2 closest to the conductive pad 322 extends from or is aligned with the side surface of the first seed layer PL1, the portion of the conductive layer ML2 closest to the conductive pad 322 directly contacting the insulating layer IN2 is increased. Due to poor adhesion between the conductive layer ML2 and the insulating layer IN2, the risk of peeling is increased.

Please still refer to FIG. 4, the second seed layer PL2 is disposed between the conductive layer ML2 next closest to the conductive pad 322 and the conductive layer ML2 closest to the conductive pad 322. The side surface of the second seed layer PL2 protrudes from the side surface of the conductive layer ML2 next closest to the conductive pad 322 by a second distance PD2. Because the thickness of the conductive layer ML2 formed on the first seed layer PL1 (i.e., the conductive layer ML2 closest to the conductive pad 322) is thicker than the thickness of the conductive layer ML2 formed on the second seed layer PL2 (i.e., the conductive layer ML2 next closest to the conductive pad 322), the distance of the side surface of the first seed layer PL1 protruding from the side surface of the conductive layer ML2 closest to the conductive pad 322 may be greater than the distance of the side surface of the second seed layer PL2 protruding from the conductive layer ML2 next closest to the conductive pad 322. Thereby, it is beneficial to ensure a secure adhesion. That is, when the first distance PD1 is greater than the second distance PD2, it is beneficial to reduce the risk of peeling, so that the reliability of the electronic device 1a can be improved.

In some embodiments, after forming the conductive layer ML2 closest to the conductive pad 322, the side surface (side edge) of the conductive layer ML2 closest to the conductive pad 322 that contacts the insulating layer IN2 may be roughened by an etching process. Microstructures such as a plurality of recesses are formed on the side edge of the conductive layer ML2 closest to the conductive pad 322. In some embodiments, the etching process may include a dry etching process, a wet etching process, or other suitable etching processes. In some embodiments, the side edge of the conductive layer ML2 closest to the conductive pad 322 has a roughness Rz of 0.08 μm to 0.8 μm, which is beneficial to reduce the risk of peeling and improve the reliability of the electronic device 1a. Specifically, if the side surface of the conductive layer ML2 closest to the conductive pad 322 is not roughened, the side surface of the conductive layer ML2 closest to the conductive pad 322 is smooth and has a smaller contact area with the insulating layer IN2, so that the peeling between the conductive layer ML2 and the insulating layer IN2 may occur.

It should be noted that the aforementioned roughness Rz in the embodiment of the present disclosure is calculated based on the cross-sectional image obtained by a scanning electron microscope (SEM). Specifically, in FIG. 4, three crest points RP1 and three trough points RV1 from top to bottom on the side edge of the conductive layer ML2 closest to the conductive pad 322 are selected, and a reference line L is set between the three crest points RP1 and the three trough points RV1. Let the numerical value of the reference line L be 0, the side toward the crest point RP1 be a positive value, and the side toward the trough point RV1 be a negative value. Calculate the numerical differences between the three groups of crest points RP1 and trough points RV1 from top to bottom. The roughness Rz is the average value of the above three sets of numerical differences. In FIG. 4, the side edge of the conductive layer ML2 closest to the conductive pad 322 includes four trough points RV1 and three crest points RP1, which is exemplary, and the present disclosure is not limited thereto. The numbers of the trough points RV1 and the crest points may be adjusted according to actual needs. In this case, the roughness Rz may be the average value of the numerical differences between the crest point RP1 and the trough point RV1 of the groups from top to bottom. It should be noted that in order to simplify the drawings, the first seed layer PL1, the second seed layer PL2 and the microstructures formed on the side edge of the conductive layer ML2 closest to the conductive pad 322 are omitted in FIG. 2 and FIG. 3.

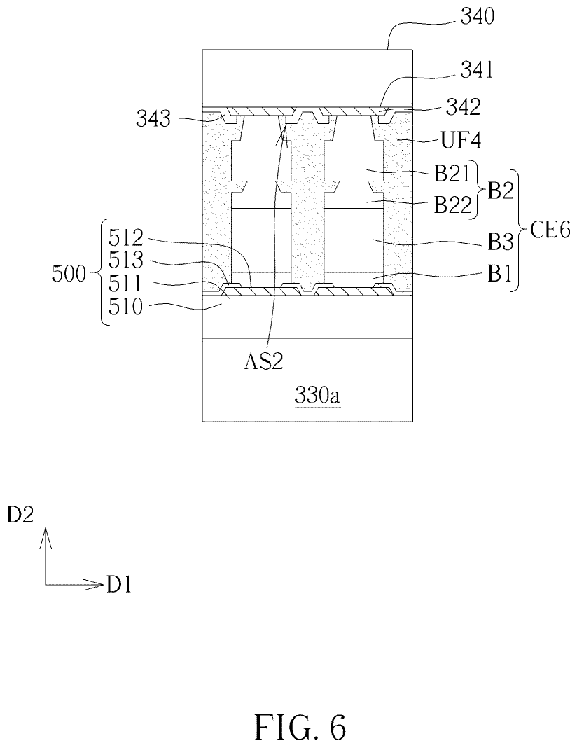

Please refer back to FIG. 1. Each of the package unit 300a may further include another circuit layer (which may refer to the circuit layer 341 in FIG. 6), another conductive pad (which may refer to the conductive pad 342 in FIG. 6) and another insulating layer (which may refer to the insulating layer 343 in FIG. 6) disposed on the active side AS2 of the chip 340. The circuit layer is disposed on the surface of the active side AS2 of the chip 340. The conductive pad is disposed on the surface of the circuit layer and electrically connected to the circuit layer. The insulating layer is disposed on the circuit layer and the conductive pad, and the insulating layer covers portions of the circuit layer and the conductive layer and exposes a portion of the conductive pad for electrical connection with other elements. The conductive pad may serve as an interface for electrical connection between the chip 340 and other elements (herein, the bonding element CE5). In other words, the chip 340 can be electrically connected to the conductive layer ML3 (see FIG. 3) of the interposer 330 through the circuit layer, the conductive pad and the bonding element CE5. For details about the circuit layer, the conductive pad and the insulating layer disposed on the active side AS2 of the chip 340, references may be made to the relevant descriptions of the circuit layer 321, conductive pad 322 and insulating layer 323 disposed on the active side AS1 of the chip 320.

The materials of the aforementioned insulating layers IN1, IN2, IN3 may independently include organic insulating materials or inorganic insulating materials. The organic insulating materials may be, for example, plastic, polyimide, acrylic materials, photoresist materials, other suitable materials or a combination thereof, but not limited thereto. The inorganic insulating materials may be, for example, silicon oxide, silicon nitride, other suitable materials, or a combinations thereof, but not limited thereto. The conductive layers ML1, ML2, and ML3 are exemplarily single-layer structures. The materials of the conductive layers ML1, ML2 and ML3 may independently include iron, aluminum, copper, other suitable materials, or a combination thereof, but not limited thereto. According to an embodiment of the present disclosure, the material of the conductive layer may include copper. In other embodiments, the conductive layers ML1, ML2 and ML3 may be multi-layer structures. For example, each of the conductive layers ML1, ML2 and ML3 may optionally further include a barrier layer (not shown). The material of the barrier layer may exemplarily include titanium (Ti), but not limited thereto. The material of the molding layer 325 may include epoxy, polydimethylsiloxane (PDMS), other suitable materials, or a combination thereof, but not limited thereto.

As shown in FIG. 1, the chip 320 can be electrically connected to the substrate 100 through the circuit structure 310, the bonding elements CE3, the interposer 200 and the bonding elements CE2. The chip 340 can be electrically connected to the substrate 100 through the bonding elements CE5, the interposer 330, the bonding elements CE4, the conductive elements CM1 in the through holes TH1, the circuit structure 310, the bonding elements CE3, the interposer 200 and the bonding elements CE2. Thereby, the chip 320 and the chip 340 can be electrically connected to other elements (not shown) through the substrate 100 and the bonding elements CE1. In addition, the chip 320 and the chip 340 can be electrically connected to each other through the bonding elements CE5, the interposer 330, the bonding elements CE4, the conductive elements CM1 in the through holes TH1 and the circuit structure 310. The chips 340 of the same package unit 300a can be electrically connected to each other through the bonding elements CE5 and the interposer 330. The plurality of package units 300a can be electrically connected to each other through the interposer 200. Thereby, it is favorable for effectively utilizing the plane space, so that the electronic device 1a can provide more diverse functions.

Please refer to FIG. 5, which is a schematic cross-sectional view showing an electronic device 1b according to another embodiment of the present disclosure. The main difference between the electronic device 1b and the electronic device 1a is that the structure of the package unit 300b is different from the structure of the package unit 300a. The main differences between the package unit 300b and the package unit 300a are as follows. In the package unit 300b, the active side AS1 of the chip 320 is configured to face upward, and a surface (not labeled) opposite to the active side AS1 of the chip 320 is fixed on the surface (not labeled) of the circuit structure 310 through the adhesive layer 326. The material of the adhesive layer 326 may include acrylic resin, urethane resin, other suitable materials, or a combination thereof, but not limited thereto.

The molding layer 325 surrounds and covers the side surfaces of the chip 320 and the surface (not labeled) of the chip 320 at the active side AS1. At least one through hole TH1 and at least one through hole TH2 are formed in the molding layer 325. The through hole TH1 is disposed at the outer side of the side surface of the chip 320 and between the circuit structure 310 and the interposer 330a, and the through hole TH2 is disposed at the inner side of the side surface of the chip 320 and between the chip 320 and the interposer 330a. In the embodiment, the molding layer 325 is exemplarily formed with a plurality of through holes TH1 and a plurality of through holes TH2.

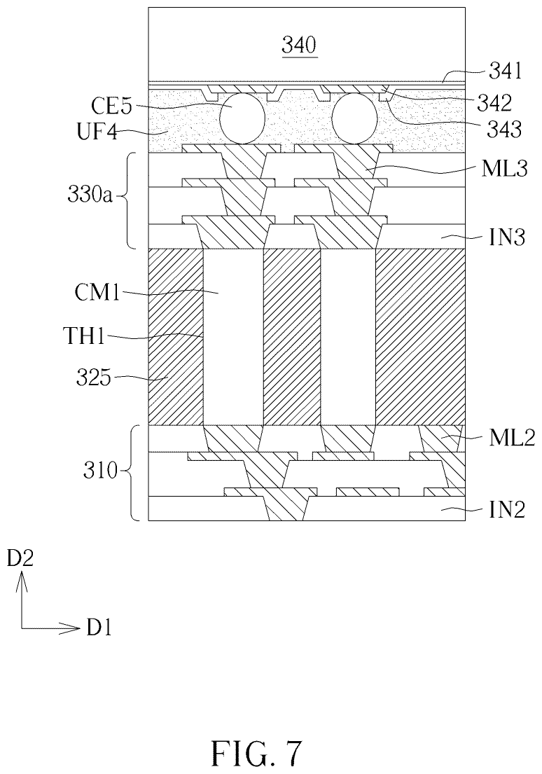

Please refer to FIG. 7 at the same time. FIG. 7 is an enlarged view of part E in FIG. 5. Two ends of each of the through holes TH1 are respectively connected to the circuit structure 310 and the interposer 330a. Each of the through holes TH1 is filled with a conductive material to form a conductive element CM1, so that the circuit structure 310 and the interposer 330a can be electrically connected through the conductive elements CM1. Specifically, the interposer 330a is exemplarily a redistribution layer structure. The interposer 330a may include at least one insulating layer IN3 and at least one conductive layer ML3. The circuit structure 310 is exemplarily a redistribution layer structure. The circuit structure 310 may include at least one insulating layer IN2 and at least one conductive layer ML2. The upper end and the lower end of the conductive element CM1 may be electrically connected to the conductive layer ML3 of the interposer 330a and the conductive layer ML2 of the circuit structure 310.

Please refer back to FIG. 5. Two ends of each of the through holes TH2 are respectively connected to the active side AS1 of the chip 320 and the interposer 330a. Each of the through holes TH2 is filled with a conductive material to form a conductive element CM2, so that the chip 320 and the interposer 330a can be electrically connected to each other through the conductive elements CM2. For example, the upper end and the lower end of the conductive element CM2 can be electrically connected to the conductive layer ML3 (see FIG. 7) of the interposer 330a and the conductive pad (which may refer to the conductive pad 322 in FIG. 4) disposed on the active side AS1 of the chip 320. For details about the conductive elements CM1 and CM2, references may be made to the relevant description of the conductive element CM1 of the electronic device 1a, and are omitted herein.

As shown in FIG. 5, the chip 320 can be electrically connected to the interposer 330a through the conductive elements CM2 in the through holes TH2, and then electrically connected to the chip 340 through the bonding elements CE5. Alternatively, the chip 320 can be electrically connected to the substrate 100 through the conductive elements CM1 in the through holes TH1, the circuit structure 310, the bonding elements CE3, the interposer 200 and the bonding elements CE2, and then electrically connected to other elements (not shown) through the substrate 100 and the bonding elements CE1.

The package unit 300b may further include at least one bridge element 500 disposed on the surface of the interposer 330a, and two adjacent ones of the plurality of chips 340 are electrically connected through the bridge element 500. Herein, the bridge element 500 is embedded in the surface of the interposer 330a, which is exemplary, and the present disclosure is not limited thereto. In other embodiments, the bridge element 500 may be disposed on the surface of the interposer 330a.

In the embodiment, each of the package units 300b includes two bridge elements 500, and any two adjacent chips 340 in each of the package unit 300b are electrically connected through the bridge element 500, but not limited thereto. The number and the disposed positions of the bridge elements 500 in each of the package unit 300b may be adjusted according to actual needs. That is, according to the actual needs, some of two adjacent chips 340 may be electrically connected to each other through the bridge element 500, while some of two adjacent chips 340 may not be electrically connected to each other through the bridge element 500. When the two adjacent chips 340 are not electrically connected to each other through the bridge element 500, the two adjacent chips 340 can be electrically connected to each other through the bonding elements CE5 and the interposer 330a according to actual needs.

Please refer to FIG. 6 at the same time. FIG. 6 is an enlarged view of part D in FIG. 5. Each of the package units 300a may further include a circuit layer 341, at least one conductive pad 342 and an insulating layer 343. The circuit layer 341 is disposed on a surface of the active side AS2 of the chip 340. The conductive pad 342 is disposed on a surface of the circuit layer 341 and is electrically connected to the circuit layer 341. The insulating layer 343 is disposed on the circuit layer 341 and the conductive pad 342. The insulating layer 343 covers portions of the circuit layer 341 and the conductive pad 342, and exposes a portion of the conductive pad 342 for electrical connection with other elements.

Each of the bridge elements 500 may include a silicon substrate 510, a circuit layer 511, at least one conductive pad 512 and an insulating layer 513. The circuit layer 511 is disposed on a surface of the silicon substrate 510. The conductive pad 512 is disposed on a surface of the circuit layer 511 and electrically connected to the circuit layer 511. The insulating layer 513 is disposed on the circuit layer 511 and the conductive pad 512. The insulating layer 513 covers portions of the circuit layer 511 and the conductive pad 512, and exposes a portion of the conductive pad 512 for electrical connection with other elements. Other details about the circuit layers 341 and 511, the conductive pads 342 and 512 and the insulating layers 343 and 513 may be the same as that of the circuit layer 321, the conductive pad 322, and the insulating layer 323 mentioned above, and are omitted herein. The silicon substrate 510 may include, for example, an epitaxial silicon substrate, a silicon carbide substrate, or a silicon on insulator (SOI) substrate, but not limited thereto. Active elements (not shown) or passive elements (not shown) may be formed in the silicon substrate 510 according to actual needs. The active element may be, for example, a transistor, and the passive element may be, for example, a capacitor, a resistor or an inductor, but not limited thereto. In other words, the bridge element 500 according to the present disclosure may include the silicon substrate 510 and a conductive layer formed on the silicon substrate 510. The conductive layer may be, for example, the conductive pad 512 or a metal interconnection layer formed in the silicon substrate 510, but not limited thereto this. With two adjacent chips 340 being electrically connected through the bridge element 500, it is beneficial to increase the transmission rate of the signal between the two adjacent chips 340, and is beneficial to transmit high frequency signals between the two adjacent chips 340.

Please refer to FIG. 5 and FIG. 6 at the same time. In FIG. 5, limited by the space of the drawing, the bonding element CE6 is represented by an elliptical cylinder. However, the elliptical cylinder can include one or a plurality of bonding elements CE6. In FIG. 6, one elliptical cylinder exemplarily includes two bonding elements CE6, but not limited thereto. The number of bonding elements CE6 included in each of the elliptical cylinders may be adjusted according to actual needs, such as the number of the signal types required to be transmitted. As shown in FIG. 6, each of the bonding elements CE6 may include a bonding portion B1, a bonding portion B2 and a solder portion B3. One end of the bonding portion B1 is electrically connected to the bridge element 500 (such as the conductive pad 512 of the bridge element 500), and the other end of the bonding portion B1 is connected to the solder portion B3. One end of the bonding portion B2 is electrically connected to the chip 340 (such as electrically connected to the chip 340 through the conductive pad 342 and the circuit layer 341), and the other end of the bonding portion B2 is connected to the solder portion B3. The bonding portion B1 is exemplarily a single-layer structure. The material of the bonding portion B1 may include copper. The material of the solder portion B3 may include tin-copper alloy (CuSn). The bonding portion B2 is exemplarily a double-layer structure, which are a metal layer B21 and a metal layer B22 in sequence from the chip 340 along a direction away from the chip 340. The materials of the metal layer B21 and the metal layer B22 may include copper, but not limited thereto. The number of the layers of each of the bonding portions B1 and B2 and the materials of the layers may be adjusted according to actual needs. As shown in FIG. 6, the bonding element CE6 is a composite element including the bonding portions B1 and B2 and the solder portion B3. The bonding portions B1 and B2 are connected to each other through the solder portion B3 to form a solder bonding connection.

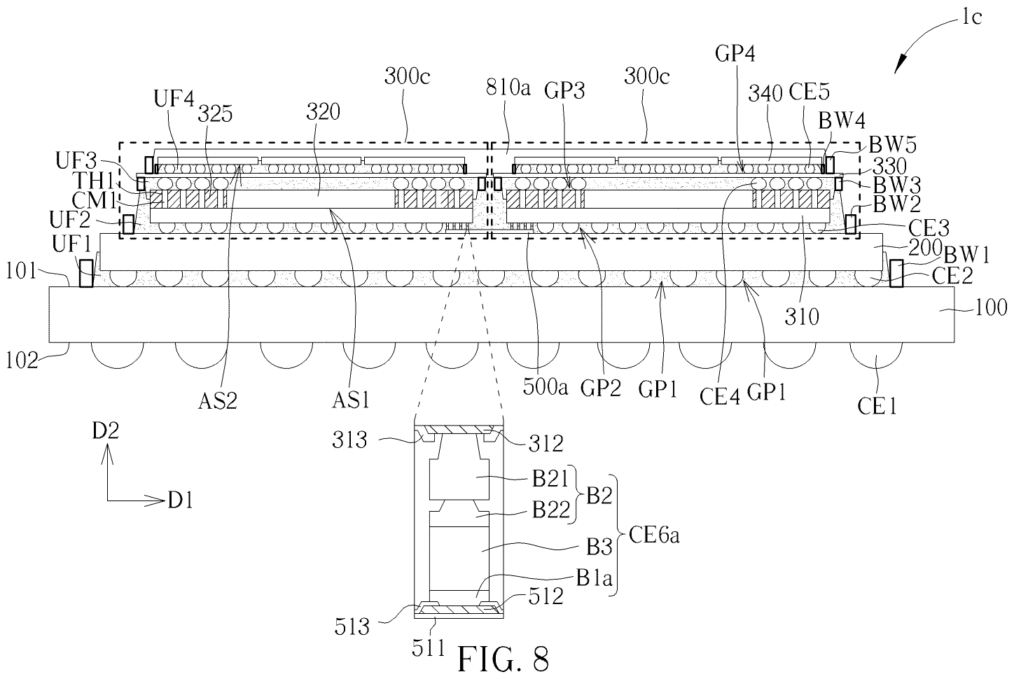

Please refer to FIG. 8, which is a schematic cross-sectional view showing an electronic device 1c according to yet another embodiment of the present disclosure. The main differences between the electronic device 1c and the electronic device 1a include that the numbers of the through holes TH1 and the conductive elements CM1 in the molding layer 325 are different, and the electronic device 1c further includes a protective layer 810a, blocking structures BW1, BW2, BW3, BW4 and BW5 and a bridge element 500a.

Specifically, in the present disclosure, the numbers of the through holes TH1 and the conductive elements CM1 in each embodiment may be adjusted according to actual needs, such as the number of the signal types required to be transmitted.

The protective layer 810a covers the upper sides and side walls of the plurality of chips 340. The protective layer 810a may be configured to protect the chips 340, so that the performance of the chips 340 may be prevented form being affected by external objects such as moisture and/or dust. The material of the protective layer 810a may include epoxy, polyimide, siloxane, silicone, other suitable materials, or a combination thereof, but not limited thereto.

The blocking structure BW1 is disposed on the upper surface of the substrate 100 and located in the peripheral region of the substrate 100. The blocking structure BW2 is disposed on the upper surface of the interposer 200 and located in the peripheral region of the interposer 200. The blocking structure BW3 is disposed on the lower surface of the interposer 330 and located in the peripheral region of the interposer 330. The blocking structures BW4 and BW5 are disposed on the upper surface of the interposer 330 and located in the peripheral region of the interposer 330, wherein the blocking structure BW5 is disposed at the outer side of the blocking structure BW4 and surrounds the blocking structure BW4. Specifically, each of the blocking structures BW1, BW2, BW3, BW4 and BW5 may have a ring structure. That is, in the top view of the electronic device 1c, each of the blocking structures BW1, BW2, BW3, BW4 and BW5 may have a closed shape. The blocking structures BW1, BW2, BW3, BW4 and BW5 may independently be a circular ring structure or a rectangular ring structure, but not limited thereto. In addition, the shapes of the blocking structures BW1, BW2, BW3, BW4 and BW5 may respectively correspond to the shapes of the substrate 100, the interposer 200 and/or the interposer 330. For example, when the substrate 100 is a circular substrate, the blocking structure BW1 may be a circular ring structure, but not limited thereto. The materials of the blocking structures BW1, BW2, BW3, BW4 and BW5 may include a metal, silicon, silicon carbide, quartz, glass, other suitable materials or a combination thereof, but not limited thereto.

The blocking structures BW1, BW2, BW3 and BW4 are disposed in the peripheral region of the electronic device 1c and respectively surround the fillers UF1, UF2, UF3 and UF4. Specifically, the blocking structures BW1, BW2, BW3 and BW4 are configured for limiting the fillers UF1, UF2, UF3 and UF4 to prevent the fillers UF1, UF2, UF3 and UF4 from flowing away before curing, which is favorable for keeping the fillers UF1, UF2, UF3 and UF4 in the gaps GP1, GP2, GP3 and GP4 between the plurality of bonding elements CE2, CE3, CE4 and CE5, so that the effect of protecting and fixing the bonding elements CE2, CE3, CE4 and CE5 can be enhanced. The blocking structure BW5 is configured for limiting the protective layer 810a to prevent the protective layer 810a from flowing away before curing, which is favorable for keeping the protective layer 810a on the upper sides and the side walls of the chips 340 and in the gap between two adjacent chips 340, so that the effect of protecting and fixing the chips 340 can be enhanced. When manufacturing the electronic device 1c, the filler UF4 is required to be filled first, and then the protective layer 810a is formed, so that the protective layer 810a also covers the filler UF4. The order of forming the protective layer 810a and the fillers UF1, UF2 and UF3 are not limited.

The bridge element 500a is disposed on the surface of the interposer 200, and two adjacent ones of the plurality of package units 300c are electrically connected through the bridge element 500a. Herein, the bridge element 500a is disposed on the surface of the interposer 200, but not limited thereto. In other embodiments, the bridge element 500a may be embedded in the surface of the interposer 200. In the embodiment, the number of the package units 300c is two and the number of the bridge element 500a is one, but not limited thereto. The numbers of the package units 300c and bridge elements 500a may be adjusted according to actual needs. In addition, when the number of package units 300c is more than three, all two adjacent package units 300c are electrically connected through the bridge elements 500a, or some of two adjacent package units 300c are electrically connected to each other through the bridge element 500a, while some of two adjacent package units 300c are not electrically connected to each other through the bridge element 500a, which may be arranged according to actual needs. When two adjacent package units 300c are not electrically connected through the bridge element 500a, the two adjacent package units 300c may be electrically connected to each other through the bonding elements CE3 and the interposer 200 according to actual needs, but not limited thereto.

The bridge element 500a may include a silicon substrate (which may refer to the silicon substrate 510 in FIG. 6) and a conductive layer disposed on the silicon substrate, such as the conductive pad 512. For other details about the bridge element 500a, references may be made to the relevant description of the bridge element 500 above, and are omitted herein. The bridge element 500a and the circuit structure 310 may be electrically connected through the bonding element CE6a. Herein, the bridge element 500a and each of the circuit structures 310 are electrically connected through four bonding elements CE6a. However, it is only exemplary. The number of the bonding elements CE6a between each of the bridge elements 500a and each of the circuit structures 310 may be adjusted according to actual needs, such as the number of the signal types required to be transmitted.

The circuit structure 310 may further include at least one conductive pad 312 corresponding to the bonding element CE6a. The conductive pad 312 is disposed on the surface of the circuit structure 310 and is electrically connected to the conductive layer (which may refer to the conductive layer ML2 in FIG. 2) in the circuit structure 310. The circuit structure 310 may further include an insulating layer 313 covering a portion of the conductive pad 312 and exposing a portion of the conductive pad 312 for electrical connection with other elements. The bonding element CE6a may include a bonding portion B1a, a bonding portion B2 and a solder portion B3. One end of the bonding portion B1a is electrically connected to the bridge element 500a (such as the conductive pad 512 of the bridge element 500a), and the other end of the bonding portion B1a is connected to the solder portion B3. One end of the bonding portion B2 is electrically connected to the circuit structure 310 (such as the conductive pad 312 of the circuit structure 310), and the other end of the bonding portion B2 is connected to the solder portion B3. The bonding portions B1a and B2 are connected to each other through the solder portion B3 to form a solder bonding connection. Herein, the bonding portion B1a is exemplarily a single-layer structure. The material of the bonding portion B1a may include copper, but not limited thereto. Herein, the bonding portion B2 is exemplarily a multi-layer structure. For example, the bonding portion B2 may be the same as the bonding portion B2 in FIG. 6, but not limited thereto. For other details about the bonding element CE6a, references may be made to the relevant description of the bonding element CE6 above, and are omitted herein.

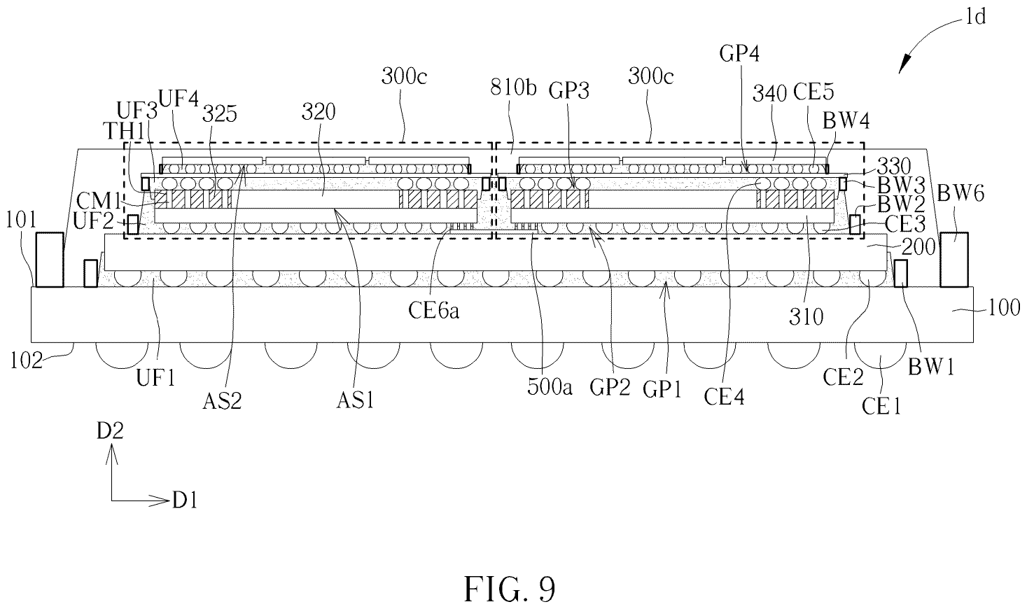

Please refer to FIG. 9, which is a schematic cross-sectional view showing an electronic device 1d according to yet another embodiment of the present disclosure. The main difference between the electronic device 1d and the electronic device 1c includes that the protective layer 810a and the blocking structure BW5 of the electronic device 1c are respectively replaced by the protective layer 810b and the blocking structure BW6. The protective layer 810b is disposed on the substrate 100. The protective layer 810b covers the plurality of package units 300c and the interposer 200, and the protective layer 810b covers the filler UF1 between the interposer 200 and the substrate 100. Specifically, the blocking structure BW6 is disposed on the upper surface of the substrate 100 and located in the peripheral region of the substrate 100. The blocking structure BW6 is disposed at the outer side of the blocking structure BW1 and surrounds the blocking structure BW1. The blocking structure BW6 is configured to limit the protective layer 810b and prevent the protective layer 810b from flowing away before curing, which is beneficial to keep the protective layer 810b inside the blocking structure BW6, so that the effect of protecting and fixing the package units 300c and the filler UF1 can be enhanced. Furthermore, in the electronic device 1d, the protective layer 810b is formed after the fillers UF1, UF2, UF3 and UF4 are all filled, so that the protective layer 810b can cover all the elements above the substrate 100 except the blocking structure BW6. For other details about the protective layer 810b and the blocking structure BW6, references may be made to the relevant descriptions of the protective layer 810a and the blocking structures BW1, BW2, BW3, BW4 and BW5 above, and are omitted herein.

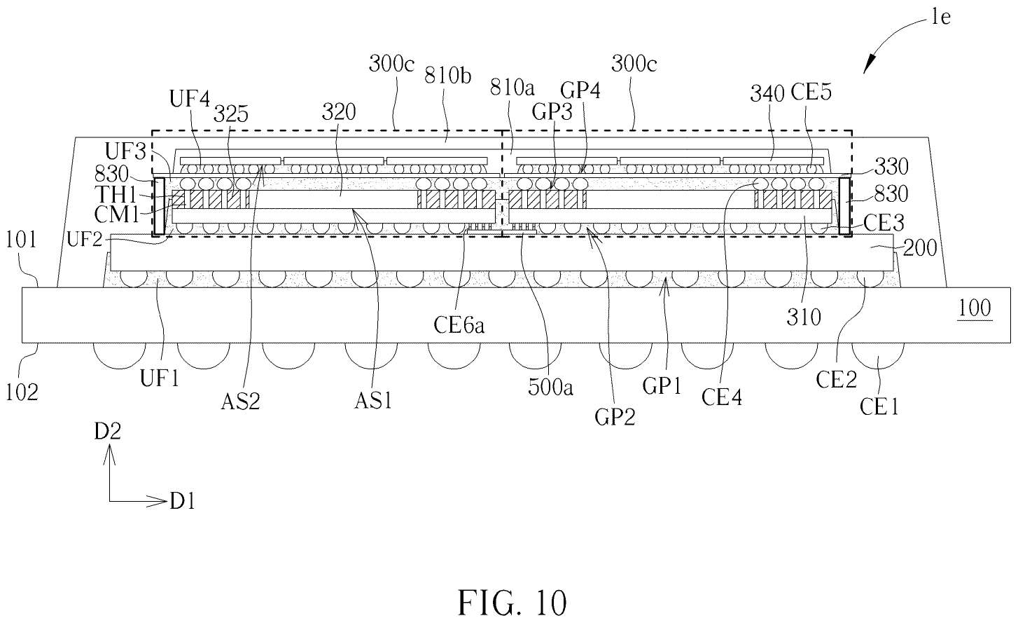

Please refer to FIG. 10, which is a schematic cross-sectional view showing an electronic device 1e according to yet another embodiment of the present disclosure. The main differences between the electronic device 1e and the electronic device 1c of FIG. 8 include that the electronic device 1e further includes a protective layer 810b and at least one supporting element 830, and the electronic device 1e is not disposed with blocking structures BW1, BW2, BW3, BW4 and BW5.

The supporting element 830 is disposed between the interposer 200 and the interposer 330, and the upper end and the lower end of the supporting element 830 respectively abut against the interposer 330 and the interposer 200. Thereby, it is beneficial to maintain the spaced distance between the interposer 330 and the interposer 200, so that elements such as the chip 320 disposed between the interposer 330 and the interposer 200 can be prevented from being crushed. In this embodiment, the supporting element 830 may include, for example, a columnar structure. There are exemplarily a plurality of supporting elements 830, and the supporting elements 830 are spaced apart from each other. For example, the plurality of supporting elements 830 may be equally spaced apart from each other, but not limited thereto. The material of the supporting element 830 may include a metal, silicon, silicon carbide, quartz, glass, other suitable materials, or a combination thereof, but not limited thereto.

For example, the electronic device 1c in FIG. 8 may be formed first, and then the blocking structures BW1, BW2, BW3, BW4 and BW5 are removed, and then the supporting element 830 is disposed between the interposer 200 and the interposer 330. Afterward, the blocking structure BW6 (which may refer to the blocking structure BW6 in FIG. 9) is disposed on the substrate 100. Next, the protective layer 810b is formed to cover the package unit 300c, the interposer 200 and the filler UF1. After the protective layer 810b is cured, the blocking structure BW6 is removed, and the electronic device 1e can be obtained. In other embodiments, the supporting element 830 can be disposed between the interposer 200 and the interposer 330 first, and then the blocking structures BW1, BW2, BW3, BW4 and BW5 are disposed to form the fillers UF1, UF2, UF3, UF4 and the protective layer 810a. Afterward, the blocking structures BW1, BW2, BW3, BW4 and BW5 are removed, and the blocking structure BW6 is disposed to form the protective layer 810b. In some embodiments, after the fillers UF1, UF2, UF3 and UF4 and the protective layers 810a and 810b are formed, the blocking structures BW1, BW2, BW3, BW4, BW5 and BW6 are not removed. That is, the electronic device 1e may further include the blocking structures BW1, BW2, BW3, BW4, BW5 and BW6. In some embodiments, the fillers UF1, UF2, UF3, and UF4 and the protective layers 810a and 810b may be formed without disposing the blocking structures BW1, BW2, BW3, BW4, BW5 and BW6. For example, the compositions of the fillers UF1, UF2, UF3 and UF4 and the protective layers 810a and 810b and the process conditions may be adjusted, so that the fillers UF1, UF2, UF3 and UF4 and the protective layers 810a and 810b may be cured before flowing away (i.e., cured faster), Accordingly, the steps for disposing the blocking structures BW1, BW2, BW3, BW4, BW5 and BW6 can be omitted, which is beneficial to simplifying the manufacturing process.

Please refer to FIG. 11, which is a schematic cross-sectional view showing an electronic device 1f according to yet another embodiment of the present disclosure. The main differences between the electronic device 1f and the electronic device 1a include that the numbers of the through holes TH1 and the conductive elements CM1 in the molding layer 325 are different, the structure of the interposer 600 is different from the structure of the interposer 200, and the electronic device 1f further includes a bridge element 500a.

The interposer 600 includes a base layer 610, a first circuit layer 620 and a second circuit layer 630. The first circuit layer 620 is disposed on the bottom surface 612 of the base layer 610, and the second circuit layer 630 is disposed on the top surface 611 of the base layer 610. The base layer 610 has at least one through hole TH3. Herein, the base layer 610 exemplarily has a plurality of through holes TH3. Each of the through holes TH3 is filled with a conductive material to form a conductive element CM3, so that the first circuit layer 620 and the second circuit layer 630 can be electrically connected to each other through the conductive elements CM3. For example, the material of the base layer 610 may include glass, but not limited thereto. Each of the first circuit layer 620 and the second circuit layer 630 may be, for example, a redistribution layer structure, but not limited thereto. With the configuration, the interposer 600 can be arranged with a larger area, and the flatness of the interposer 600 can be improved. According to an embodiment of the present disclosure, the diameter of the through hole TH3 varies along the thickness direction of the base layer 610 (such as parallel to the vertical direction D2). For example, two ends of the through hole TH3 are wider and the middle region between the two ends is narrower, or the diameter is decreased from one end to the other end, but not limited thereto. In addition, according to an embodiment of the present disclosure, in the cross-sectional view of the through hole TH3, the profile of the edges of the through hole TH3 in the base layer 610 are two arc-shaped edges facing each other. In addition, according to an embodiment of the present disclosure, the ratio of the depth to the width of the through hole TH3 is 2 to 20, and preferably be 5 to 20. The depth is defined as the distance from one end of the through hole TH3 to the other end of the through hole TH3. The width is defined as the smaller one of the two diameters of the two ends of the through hole TH3.

The bridge element 500a is disposed on the top surface 601 of the interposer 600, and two adjacent ones of the plurality of package units 300d are electrically connected through the bridge element 500a. For other details about the bridge element 500a and the bonding element CE6a, references may be made to the relevant description of FIG. 8 above, and are omitted herein.

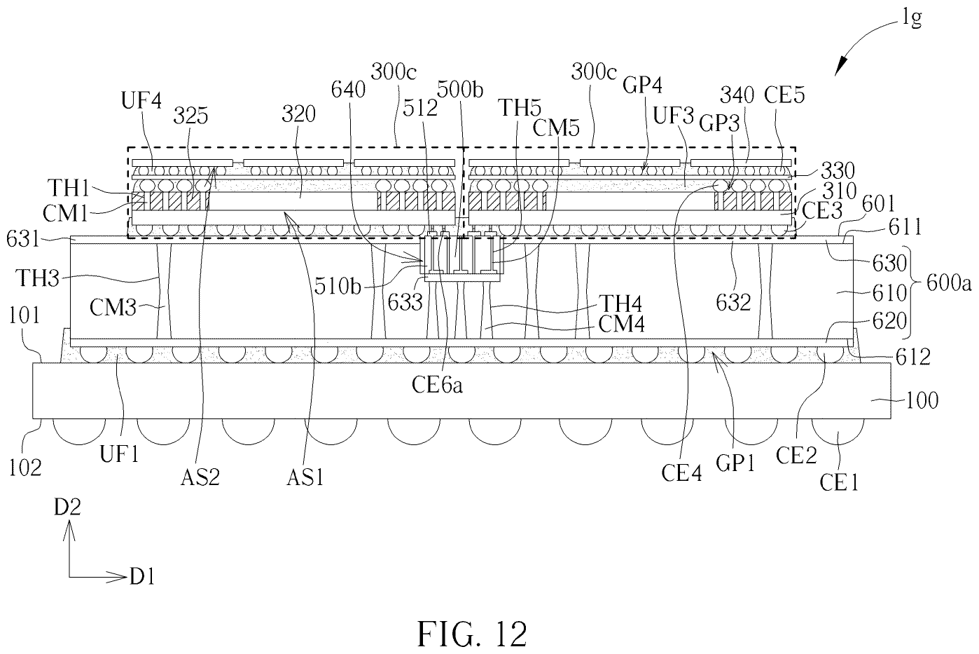

Please refer to FIG. 12, which is a schematic cross-sectional view showing an electronic device 1g according to yet another embodiment of the present disclosure. The main differences between the electronic device 1g and the electronic device 1f include that the structure of the interposer 600a is different from the structure of the interposer 600, and the structure of the bridge element 500b is different from the structure of the bridge element 500a.

Specifically, the base layer 610 further includes a recess portion 640 recessed downward relative to the top surface 611 of the base layer 610, so that the second circuit layer 630 is separated into a first region 631, a second region 632 and a third region 633. The first region 631 and the second region 632 are oppositely disposed at two sides of the recess portion 640 and are separated from each other along the horizontal direction D1. The third region 633 is disposed between the first region 631 and the second region 632 and corresponds to the recess portion 640. The third region 633 overlaps the recess portion 640 in the vertical direction D2.

The base layer 610 has at least one through hole TH3 disposed between the first region 631 of the second circuit layer 630 and the first circuit layer 620 or between the second region 632 of the second circuit layer 630 and the first circuit layer 620, and at least one through hole TH4 disposed between the third region 633 of the second circuit layer 630 and the first circuit layer 620. Herein, the base layer 610 exemplarily has a plurality of through holes TH3 and a plurality of through holes TH4. Each of the through holes TH3 is filled with a conductive material to form a conductive element CM3, so that the first region 631 and the second region 632 of the second circuit layer 630 can be electrically connected to the first circuit layer 620 through the conductive elements CM3. Each of the through holes TH4 is filled with a conductive material to form a conductive element CM4, so that the third region 633 of the second circuit layer 630 can be electrically connected to the first circuit layer 620 through the conductive elements CM4. In addition, the heights of the through hole TH4 and the conductive element CM4 in the vertical direction D2 are smaller than the heights of the through hole TH3 and the conductive element CM3 in the vertical direction D2. For other details about the interposer 600a, references may be made to the relevant description of the interposer 600 above, and are omitted herein.

In the embodiment, the bridge element 500b is disposed between the first region 631 and the second region 632, and the two adjacent package units 300c are electrically connected through the bridge element 500b. Specifically, the bridge element 500b is embedded in the top surface 601 of the interposer 600a. Herein, the bridge element 500b is disposed in the recess portion 640, and the bridge element 500b is disposed in the third region 633 of the second circuit layer 630. The bridge element 500b includes a silicon substrate 510b. At least one through hole TH5 is formed in the silicon substrate 510b. Herein, the silicon substrate 510b exemplarily has a plurality of through holes TH5. Each of the through holes TH5 is filled with a conductive material to form a conductive element CM5. The conductive element CM5 may also be called a through silicon via (TSV) element. The upper end of the conductive element CM5 is electrically connected to the circuit structure 310 of each of the package units 300c through the bonding element CE6a. The lower end of the conductive element CM5 is electrically connected to the third region 633 of the second circuit structure 630. In addition, the bridge element 500b may further include at least one conductive pad 512 disposed on the surface of the bridge element 500b. The conductive element CM5 is electrically connected to the bonding element CE6a through the conductive pad 512. The circuit structure 310 may further include at least one conductive pad (which may refer to the conductive pad 312 in FIG. 8) disposed on the lower surface of the circuit structure 310, and the conductive layer (which may refer to the conductive layer ML2 in FIG. 2) in the circuit structure 310 is electrically connected to the bonding element CE6a through the conductive pad. For other details about the bridge element 500b and the bonding element CE6a, references may be made to the relevant descriptions of the bridge element 500a and the bonding element CE6a above, and are omitted herein.

In the embodiment, the two adjacent package units 300c are electrically connected through the bridge element 500b, and the signal can be transmitted through the bridge element 500b. The transmission path may be, for example, from one of the package units 300c downward through the bonding elements CE6a, the conductive elements CM5, and the third region 633 of the second circuit layer 630 in sequence, and then upwardly through the conductive elements CM5 and the bonding elements CE6a to the other package unit 300c in sequence. In addition, each of the two package units 300c can also be electrically connected to the substrate 100 and transmits signals through the bridge element 500b. For example, the transmission path may include, for example, from one of the package units 300c downward through the bonding elements CE6a, the conductive elements CM5 and the third region 633 of the second circuit layer 630, the conductive elements CM4, the first circuit layer 620 and the bonding elements CE2 to the substrate 100 in sequence.

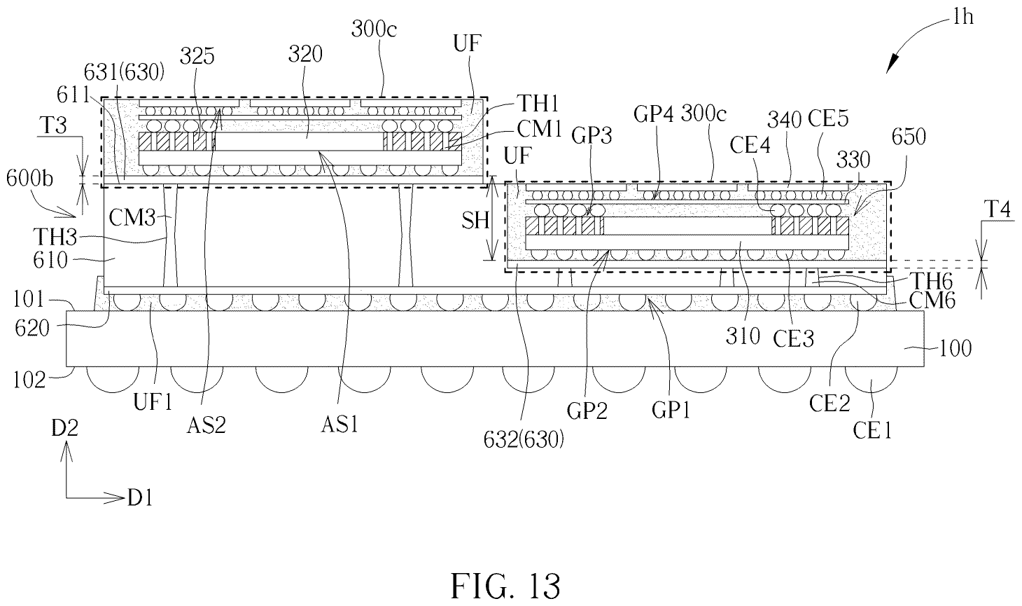

Please refer to FIG. 13, which is a schematic cross-sectional view showing an electronic device 1h according to yet another embodiment of the present disclosure. The main differences between the electronic device 1h and the electronic device 1g include that the structure of the interposer 600b is different from the structure of the interposer 600a, the electronic device 1h is not disposed with the bridge element 500b, and the package unit 300c is disposed in the filler UF.

Specifically, the base layer 610 includes a recess portion 650 recessed downward relative to the top surface 611 of the base layer 610, and separates the second circuit layer 630 into a first region 631 and a second region 632. The second region 632 corresponds to the recess portion 650, and the second region 632 overlaps the recess portion 650 in the vertical direction D2. The first region 631 corresponds to the region other than the recess portion 650, and the first region 631 does not overlap the recess portion 650 in the vertical direction D2. One of the two package units 300c (herein, the package unit 300c at the left side) is disposed on the top surface 611 of the base layer 610, and is indirectly disposed on the top surface 611 of the base layer 610 through the first region 631 of the second circuit layer 630. The other one of the package units 300c (herein, the package unit 300c at the right side) is disposed on the top surface of the recess portion 650, and is indirectly disposed on the top surface of the recess portion 650 through the second region 632 of the second circuit layer 630.

There is a height difference SH between the top surface of the first region 631 and the top surface of the second region 632 in the vertical direction D2. The height difference SH may be greater than or equal to the height (not labeled) of the package unit 300c in the vertical direction D2. The thickness T3 of the first region 631 in the vertical direction D2 may be equal to the thickness T4 of the second region 632 in the vertical direction D2, but not limited thereto. As mentioned above, the second circuit layer 630 may be a redistribution layer structure, and the thickness of each region of the second circuit layer 630 may be adjusted according to the complexity of the redistribution. In other words, in other embodiments, the thickness T3 may be less than or greater than the thickness T4.

The base layer 610 has at least one through hole TH3 disposed between the first region 631 of the second circuit layer 630 and the first circuit layer 620, and at least one through hole TH6 is disposed between the second region 632 of the second circuit layer 630 and the first circuit layer 620. Herein, the base layer 610 exemplarily has a plurality of through holes TH3 and a plurality of through holes TH6. Each of the through holes TH3 is filled with a conductive material to form a conductive element CM3, so that the first region 631 of the second circuit layer 630 can be electrically connected to the first circuit layer 620 through the conductive elements CM3. Each of the through holes TH6 is filled with a conductive material to form a conductive element CM6, so that the second region 632 of the second circuit layer 630 can be electrically connected to the first circuit layer 620 through the conductive elements CM6. In addition, the heights (not labeled) of the through hole TH6 and the conductive element CM6 in the vertical direction D2 are smaller than the heights (not labeled) of the through hole TH3 and the conductive element CM3 in the vertical direction D2. For other details about the interposer 600b, references may be made to the relevant descriptions of the interposer 600 and the interposer 600a above, and are omitted herein.

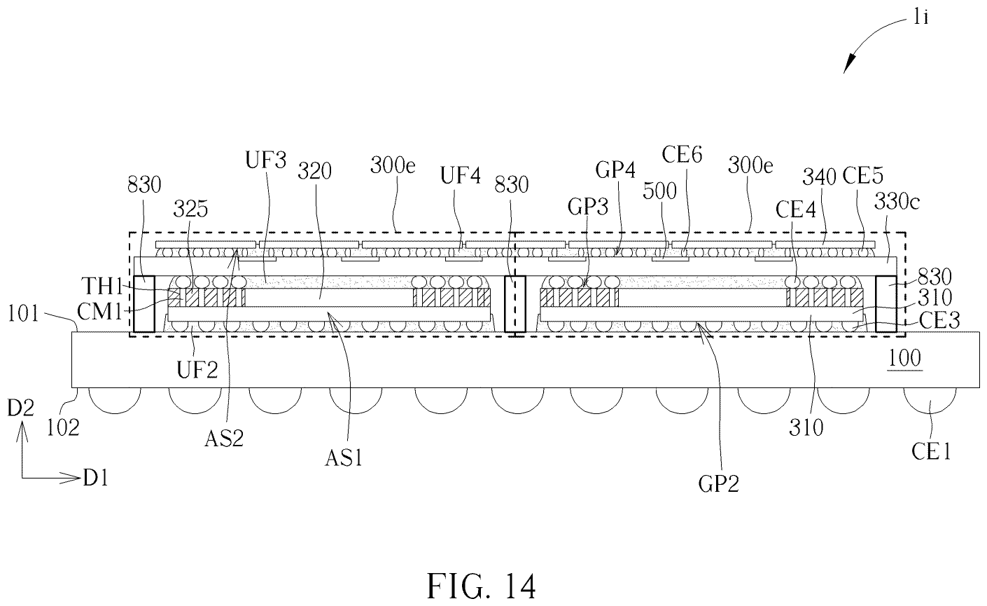

Please refer to FIG. 14, which is a schematic cross-sectional view showing an electronic device 1i according to yet another embodiment of the present disclosure. The main differences between the electronic device 1i and the electronic device 1a include that the numbers of through holes TH1 and conductive elements CM1 in the molding layer 325 are different, each of the package units 300e further includes at least one bridge element 500, the two package units 300e share an interposer 330c, the electronic device 1i further includes at least one supporting element 830, and the electronic device 1i omits the interposer 200 and the bonding elements CE2.

Specifically, in the electronic device 1i, the two independent interposers 330 in the electronic device 1a are replaced by a single interposer 330c. The electronic device 1i further includes a plurality of bridge elements 500 disposed on the surface of the interposer 330c, which are exemplarily embedded in the surface of the interposer 330c herein. Moreover, every two adjacent chips 340 are electrically connected through the bridge element 500. With the two package units 300e sharing the same interposer 330c, it is favorable for improving the assembling efficiency.

The supporting element 830 is disposed between the substrate 100 and the interposer 330c, and the upper end and the lower end of the supporting element 830 respectively abut against the interposer 330c and the substrate 100. Thereby, it is beneficial to maintain the spaced distance between the interposer 330c and the substrate 100, so that elements such as the chip 320 disposed between the interposers 330c and the substrate 200 can be prevented from being crushed. In the embodiment, there are exemplarily a plurality of supporting elements 830, and the supporting elements 830 are spaced apart from each other. For example, the plurality of supporting elements 830 may be equally spaced apart from each other, but not limited thereto. In addition, one or some supporting elements 830 may be disposed in the peripheral region of the electronic device 1i, such as at the outer side of the chip 320, and one or some supporting elements 830 may be disposed in the central region of the electronic device 1i, such as at the inner side of the chip 320 or between the two chips 320. Thereby, the supporting effect provided by the supporting element 830 can be improved. For other details about the supporting element 830, references may be made to relevant description above.

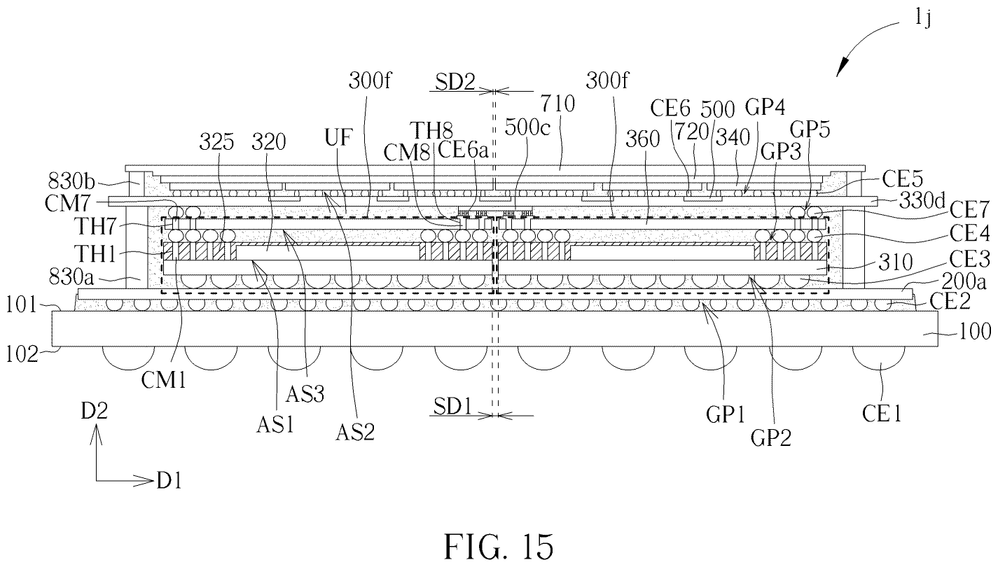

Please refer to FIG. 15, which is a schematic cross-sectional view showing an electronic device 1j according to yet another embodiment of the present disclosure. The electronic device 1j includes at least two package units 300f, an interposer 330d and a plurality of chips 340. The at least two package units 300f are disposed adjacent to each other, and each of the package units 300f sequentially includes a circuit structure 310, a chip 320 and a chip 360 along the vertical direction D2. The chip 320 is disposed on the circuit structure 310 and electrically connected to the circuit structure 310. The chip 360 is disposed on the chip 320 and electrically connected to the circuit structure 310. The interposer 330d is disposed on the at least two package units 300f and is electrically connected to the at least two package units 300f. The plurality of chips 340 are disposed on the interposer 330d and are electrically connected to the interposer 330d.

The chip 360 may be, for example, a system on chip (SoC), a dynamic random-access memory (DRAM) chip, a high bandwidth memory (HBM) chip, a photonic integrated circuit (PIC) chip, an application specific integrated circuit (ASIC) chip, but not limited thereto. According to an embodiment of the present disclosure, the chip 360 may be an unpackaged chip, but not limited thereto. Herein, the size of the chip 360 in the horizontal direction D1 is larger than the size of the chip 320 in the horizontal direction D1, and the size of the chip 320 in the horizontal direction D1 is larger than the size of the chip 340 in the horizontal direction D1, which is exemplary and the present disclosure is not limited thereto.

The electronic device 1j may optionally further include a substrate 100 and an interposer 200a. The interposer 200a is disposed on the substrate 100, wherein the at least two package units 300f are disposed on the interposer 200a and are electrically connected to the substrate 100 through the interposer 200a. The interposer 200a is exemplarily a redistribution layer structure. According to an embodiment of the present disclosure, the interposer 200a includes a base, conductive layers formed on the upper surface and the lower surface of the base, and a through hole penetrating through the base. The substrate may include glass or silicon.

Each of the package units 300f may further include a molding layer 325 surrounding the side surfaces of the chip 320. At least one through hole TH1 is formed in the molding layer 325. The through hole TH1 is filled with a conductive material to form a conductive element CM1. A plurality of bonding elements CE4 are disposed between the molding layer 325 and the chip 360. The conductive elements CM1 and the chip 360 can be electrically connected through the bonding elements CE4. Specifically, the active side AS3 of the chip 360 is configured to face downward, and the chip 360 and the chip 320 can be electrically connected through the bonding elements CE4, the conductive elements CM1 and the circuit structure 310.

The electronic device 1j may optionally further include a bridge element 500. The bridge element 500 is disposed on the upper surface of the interposer 330d, wherein the bridge element 500 includes a silicon substrate (which may refer to the silicon substrate 510 in FIG. 6) and a conductive layer (such as the conductive pad 512 in FIG. 6) formed in the silicon substrate. Two adjacent ones of the plurality of the chips 340 are electrically connected through the bridge element 500.

The electronic device 1j may optionally further include a bridge element 500c. The bridge element 500c is disposed on the lower surface of the interposer 330d, wherein the bridge element 500c includes a silicon substrate (which may refer to the silicon substrate 510 in FIG. 6) and a conductive layer (such as the conductive pad 512 in FIG. 6) formed on the silicon substrate. The at least two package units 300f are electrically connected through the bridge element 500c.

Specifically, at least one through hole TH8 can be formed in the periphery of the chip 320 adjacent to the interior of the electronic device 1j (or adjacent to the periphery of the other package unit 300f). The through hole TH8 is filled with a conductive material to form a conductive element CM8. At least one bonding element CE6a is disposed between the chip 360 and the interposer 330d. The bonding element CE6a is electrically connected to the conductive element CM8 of the chip 360 and the conductive layer of the bridge element 500c. Thereby, the chips 360 of the two package units 300f are electrically connected through the bridge element 500c, and the chips 320 of the two package units 300f can also be electrically connected through the bridge element 500c.

At least one through hole TH7 may be formed at the periphery of the chip 360 adjacent to the outer side of the electronic device 1j (or away from the periphery of the other package unit 300f). The through hole TH7 is filled with a conductive material to form a conductive element CM7. At least one bonding element CE7 is disposed between the chip 360 and the interposer 330d, and the bonding element CE7 is electrically connected to the conductive element CM7 of the chip 360 and the conductive layer (which may refer to the conductive layer ML3 in FIG. 7) in the interposer 330d. Thereby, the chips 320, 360, and 340 can be electrically connected to each other through the circuit structure 310, the conductive elements CM1, the bonding elements CE4, the conductive elements CM7, the bonding elements CE7, the interposer 330d, and the bonding elements CE5. The materials of the conductive elements CM7 and CM8 may be the same as that of the conductive element CM1, and are omitted herein. In addition, it should be noted that FIG. 15 only shows the wires (i.e., the conductive elements CM7 and CM8) that penetrate the chip 360 in the vertical direction D2. Other wires (not shown) may also be formed in the chip 360 to connect the active elements (not shown) and/or the passive elements (not shown) in the chip 360, and the other wires can also be electrically connected to the conductive elements CM7 and CM8.

In the electronic device 1j, there is a first spaced distance SD1 existing between the two package units 300f, there is a second spaced distance SD2 existing between two adjacent ones of the plurality of chips 340, and the first spaced distance SD1 may be, for example, greater than the second spaced distance SD2. Thereby, when the number of package units 300f is the same, it is beneficial to carry more chips 340, so that the arrangement of the electronic elements in the electronic device 1j can be denser. The aforementioned first spaced distance SD1 may be defined as the spaced distance between the circuit structures 310 of two adjacent package units 300f in the horizontal direction D1, and the aforementioned second spaced distance SD2 may be defined as the spaced distance between the two adjacent chips 340 in the horizontal direction D1. According to an embodiment of the present disclosure, the second spaced distance SD2 may be 50 μm to 100 μm. Thereby, the length of the bridge element 500 is moderate. On one hand, the transmission rate of the signal can be improved through the bridge element 500. On the other hand, the manufacturing cost of the bridge element 500 is not excessively high. In other embodiments, when two adjacent chips 340 are not electrically connected through the bridge element 500, the second spaced distance SD2 between the two adjacent chips 340 may be 600 μm to 800 μm, but not limited thereto.

The electronic device 1j may optionally further include a heat dissipating structure 710. The heat dissipating structure is disposed on the plurality of chips 340. Thereby, it is beneficial to improve the heat dissipating effect of the electronic device 1j. The electronic device 1j may optionally further include a thermal conductive material 720. The thermal conductive material 720 may be disposed between the heat dissipating structure 710 and the plurality of chips 340. Thereby, the heat dissipating effect of the electronic device 1j can be further improved. In addition, the thermal conductive material 720 may be optionally filled the gap between the heat dissipating structure 710 and the plurality of chips 340. Thereby, it is beneficial to conduct heat energy generated by the chips 340 to the heat dissipating structure 710 through the thermal conductive material 720, and then the heat energy can be conduct from the heat dissipating structure 710 to the outside of the electronic device 1j. The material of the heat dissipating structure 710 may include a metal, silicon, silicon carbide, graphite, graphene, other suitable materials, or a combination thereof, but not limited thereto. The thermal conductive material 720 may include a metal, graphite, graphene, other suitable materials, or a combination thereof, but not limited thereto.

The electronic device 1j may optionally further include at least one supporting element 830a and at least one supporting element 830b. The supporting element 830a is disposed between the interposer 200a and the interposer 330d, and the upper end and the lower end of the supporting element 830a respectively abut against the interposer 330d and the interposer 200a. Thereby, it is beneficial to maintain the spaced distance between the interposer 330d and the interposer 200a, so that elements such as the chips 320 and 360 disposed between the interposer 330d and the interposer 200a can be prevented from being crushed. The supporting element 830b is disposed between the interposer 330d and the heat dissipating structure 710, and the upper end and the lower end of the supporting element 830b respectively abut against the heat dissipating structure 710 and the interposer 330d. Thereby, it is beneficial to maintain the spaced distance between the heat dissipating structure 710 and the interposer 330d, so that elements such as the chip 340 disposed between the heat dissipating structure 710 and the interposer 330d can be prevented from being crushed. In the embodiment, each of the supporting elements 830a and 830b may include, for example, a columnar structure or a non-closed ring structure, but not limited thereto. A single supporting element 830a with an opening (not shown) or a plurality of supporting elements 830a with a gap for the filler UF to be injected into the gaps GP1, GP2, GP3, GP4 and GP5 between the bonding elements CE2, CE3, CE4, CE5 and CE7 are all suitable for the present disclosure. In the embodiment, the supporting elements 830a and 830b are columnar structures. There are exemplarily a plurality of the supporting elements 830a and a plurality of the supporting elements 830b, and the supporting elements 830a and 830b are spaced apart from each other. For example, the plurality of the supporting elements 830a and 830b may be equally spaced apart from each other, but not limited thereto. The materials of the supporting elements 830a and 830b may be the same as that of the supporting element 830 mentioned above, and are omitted herein.

In the embodiment, the filler UF is disposed in the gaps GP1, GP2, GP3, GP4 and GP5 between the bonding elements CE2, CE3, CE4, CE5 and CE7, disposed between the interposer 200a and the heat dissipating structure 710, and disposed in the remaining gaps (not labeled) between the supporting elements 830a and 830b at the left side and the right side. Thereby, the filler UF can provide the effect of protecting and fixing the elements disposed between the interposer 200a and the heat dissipating structure 710, between the supporting elements 830a at the left side and the right side, and between the supporting elements 830b at the left side and the right side.

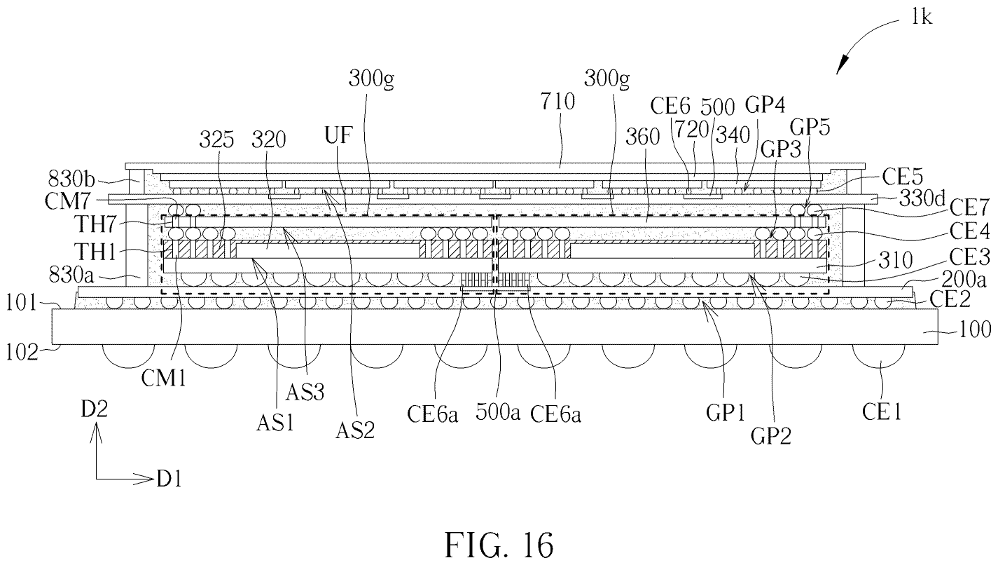

Please refer to FIG. 16, which is a schematic cross-sectional view showing an electronic device 1k according to yet another embodiment of the present disclosure. The main differences between the electronic device 1k and the electronic device 1j include that the electronic device 1k is disposed with a bridge element 500a in the interposer 200a, and the bridge element 500c disposed on the lower surface of the interposer 330d is omitted. The bridge element 500a is disposed on the surface of the interposer 200a. Herein, the bridge element 500a is exemplarily embedded in the surface of the interposer 200a. The bridge element 500a may include a silicon substrate (which may refer to the silicon substrate 510 in FIG. 6) and a conductive layer (which may refer to the conductive pad 512 in FIG. 8) formed on the silicon substrate, and at least two package units 300g are electrically connected through the bridge element 500a. For details about the bridge element 500a, references may be made to the relevant description of FIG. 8, and are omitted herein. In addition, since the bridge element 500c disposed on the lower surface of the interposer 330d is omitted in the electronic device 1k, the through holes TH8 and the conductive elements CM8 disposed in the through holes TH8 are also omitted in the chip 360 accordingly. For other details about the electronic device 1k, references may be made to the relevant description of the electronic device 1j, and are omitted herein.

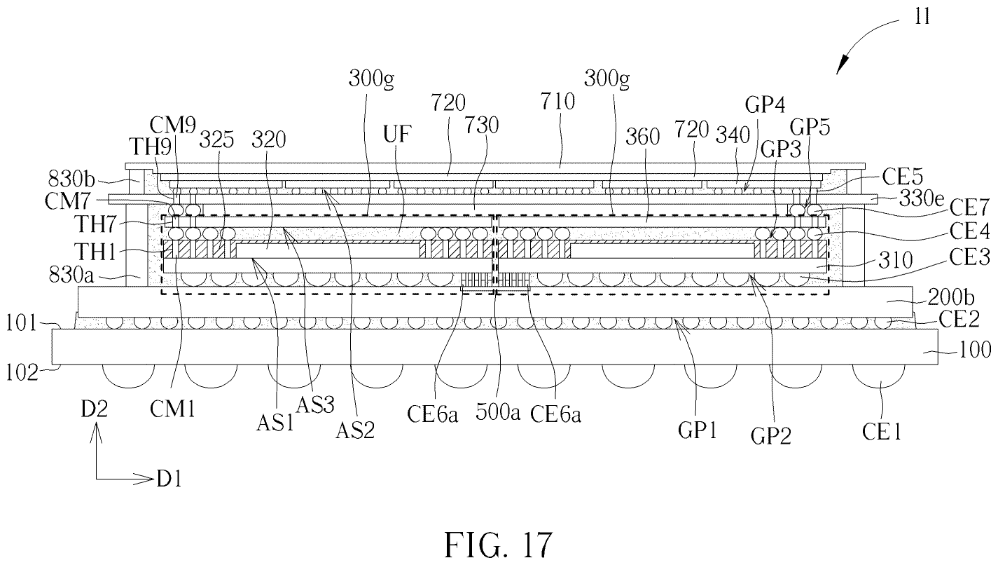

Please refer to FIG. 17, which is a schematic cross-sectional view showing an electronic device 1l according to yet another embodiment of the present disclosure. The main differences between the electronic device 1l and the electronic device 1k include that the bridge element 500 is omitted in the electronic device 1l, and the electronic device 1l further includes a thermal conductive material 730. The thermal conductive material 730 is disposed between the chip 360 and the interposer 330e, and the thermal conductive material 730 is disposed between the bonding elements CE7 at the left side and the right side. With the thermal conductive material 730, the heat dissipating effect of the electronic device 1l can be further improved. For details about the thermal conductive material 730, references may be made to the relevant description of the thermal conductive material 720 above, and are omitted herein.

In addition, at least one through hole TH9 may be formed at the periphery of the interposer 330e adjacent to the outer side of the electronic device 1l. The through hole TH9 is filled with a conductive material to form a conductive element CM9. Two ends of the conductive element CM9 may be electrically connected to the bonding element CE7 and the bonding element CE5. Thereby, the chip 320, the chip 360 and the chip 340 can be electrically connected to each other through the circuit structure 310, the conductive elements CM1, the bonding elements CE4, the conductive elements CM7, the bonding elements CE7, the conductive elements CM9 and the bonding elements CE5. For other details about the electronic device 1l, references may be made to the relevant description of the electronic device 1k, and are omitted herein.

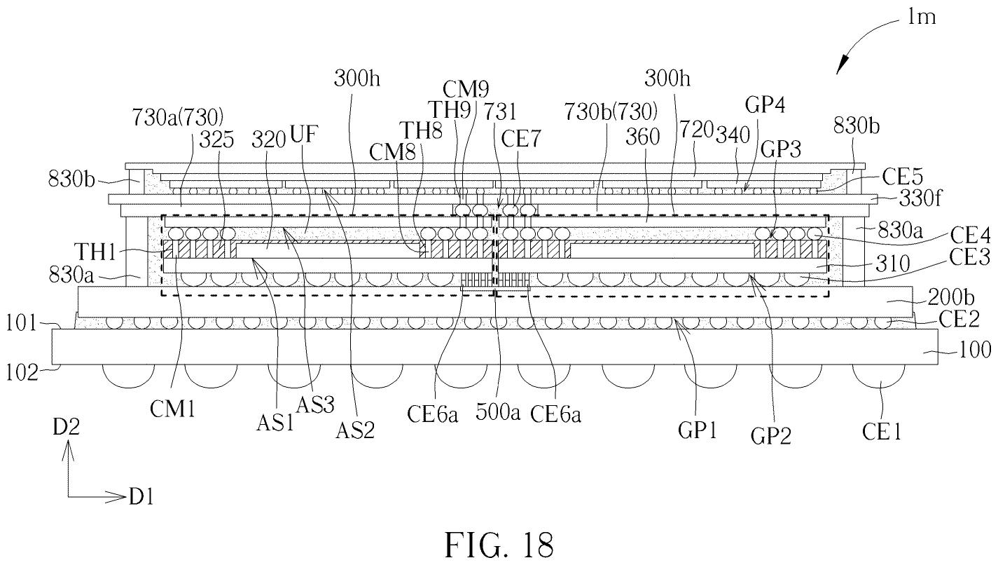

Please refer to FIG. 18, which is a schematic cross-sectional view showing an electronic device 1m according to yet another embodiment of the present disclosure. The main differences between the electronic device 1m and the electronic device 1l include that the disposed location of the thermal conductive material 730 is different, and the through hole TH7 and the conductive element CM7 are replaced by the through hole TH8 and the conductive element CM8. For details about the through hole TH8 and the conductive element CM8, references may be made to the relevant description of FIG. 15. Specifically, the thermal conductive material 730 is disposed between the interposer 330f and the chip 360. The thermal conductive material 730 has an opening 731. The thermal conductive material 730 is separated into a first portion 730a and a second portion 730b by the opening 731. The left side of first portion 730a is disposed between the supporting element 830a and the interposer 330f, and extends leftward to the outer side of the supporting element 830a. The right side of the second portion 730b is disposed between the supporting element 830a and the interposer 330f, and extends rightward to the outer side of the supporting element 830a. Thereby, it is beneficial to conduct heat energy inside the electronic device 1m to the outside form two sides of the electronic device 1m through the first portion 730a and the second portion 730b of the thermal conductive material 730. For other details about the electronic device 1m, references may be made to the relevant description of the electronic device 1l, and are omitted herein.

In the electronic device according to the present disclosure, with the package unit including a first chip and a plurality of second chips, and the first chip overlapping at least two of the plurality of second chips, or with the package unit including a first chip and a second chip in the vertical direction and the electronic device including a third chip disposed on the package unit in the vertical direction, it is beneficial to increase the maximum applied rate of planar space, so that the arrangement of the electronic elements in the electronic device can be denser, and the current trend of miniaturization of electronic products can be satisfied.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate;
a first interposer disposed on the substrate; and
a plurality of package units disposed on the first interposer, wherein along a vertical direction, one of the plurality of package units sequentially comprises:
a circuit structure disposed on the first interposer and electrically connected to the first interposer;
a first chip disposed on the circuit structure and electrically connected to the circuit structure; and
a plurality of second chips disposed on the first chip and electrically connected to the circuit structure;
wherein the first chip overlaps at least two of the plurality of second chips, and the plurality of package units are electrically connected to the substrate through the first interposer.

2. The electronic device of claim 1, wherein the one of the plurality of package units further comprises:
a second interposer disposed between the first chip and the plurality of second chips along the vertical direction and electrically connected to the first chip and the plurality of second chips.

3. The electronic device of claim 2, wherein the one of the plurality of package units further comprises a bridge element disposed on a surface of the second interposer, the bridge element comprises a silicon substrate and a conductive layer formed on the silicon substrate, and two adjacent ones of the plurality of second chips are electrically connected through the bridge element.

4. The electronic device of claim 2, further comprising:
at least one supporting element disposed between the first interposer and the second interposer, wherein an upper end and a lower end of the supporting element respectively abut against the second interposer and the first interposer.

5. The electronic device of claim 1, further comprising:
a bridge element disposed on a surface of the first interposer, wherein the bridge element comprises a silicon substrate and a conductive layer formed on the silicon substrate, and two adjacent ones of the plurality of package units are electrically connected through the bridge element.

6. The electronic device of claim 1, further comprising:
a plurality of bonding elements disposed between the first interposer and the circuit structure, wherein there is a gap existing between the plurality of bonding elements; and
a filler disposed in the gap.

7. The electronic device of claim 1, further comprising:
a first protective layer covering upper sides and sidewalls of the plurality of second chips.

8. The electronic device of claim 1, further comprising:
a second protective layer covering the plurality of package units and the first interposer.

9. The electronic device of claim 1, wherein the first interposer comprises:
a base layer having a through hole;
a first circuit layer disposed on a bottom surface of the base layer; and
a second circuit layer disposed on a top surface of the base layer, wherein the first circuit layer and the second circuit layer are electrically connected through the through hole of the base layer.

10. The electronic device of claim 9, wherein the second circuit layer comprises a first region and a second region separated from each other along a horizontal direction, the electronic device further comprises a bridge element disposed between the first region and the second region, the bridge element comprises a silicon substrate and a conductive layer formed on the silicon substrate, and two adjacent ones of the plurality of package units are electrically connected through the bridge element.

11. The electronic device of claim 9, wherein the base layer further comprises a recess portion recessed downward relative to the top surface of the base layer, the plurality of package units comprise a first package unit and a second package unit, the first package unit is disposed on a top surface of the recess portion, and the second package unit is disposed on the top surface of the base layer.

12. An electronic device, comprising:
at least two package units disposed adjacent to each other, wherein along a vertical direction, any one of the at least two package units sequentially comprises:
a circuit structure;
a first chip disposed on the circuit structure and electrically connected to the circuit structure; and
a second chip disposed on the first chip and electrically connected to the circuit structure;
a first interposer disposed on the at least two package units and electrically connected to the at least two package units; and
a plurality of third chips disposed on the first interposer and electrically connected to the first interposer.

13. The electronic device of claim 12, further comprising:
a substrate; and
a second interposer disposed one the substrate, wherein the at least two package units are disposed on the second interposer and are electrically connected to the substrate through the second interposer.

14. The electronic device of claim 13, further comprising:
a bridge element disposed on a surface of the second interposer, wherein the bridge element comprises a silicon substrate and a conductive layer formed on the silicon substrate, and the at least two package units are electrically connected through the bridge element.

15. The electronic device of claim 12, wherein there is a first spaced distance existing between the at least two package units, there is a second spaced distance existing between two adjacent ones of the plurality of third chips, and the first spaced distance is greater than the second spaced distance.

16. The electronic device of claim 12, further comprising:
a bridge element disposed on a surface of the first interposer, wherein the bridge element comprises a silicon substrate and a conductive layer formed on the silicon substrate, and the second chips of the at least two package units are electrically connected through the bridge element.

17. The electronic device of claim 12, further comprising:
a bridge element disposed on a surface of the first interposer, wherein the bridge element comprises a silicon substrate and a conductive layer formed on the silicon substrate, and two adjacent ones of the plurality of third chips are electrically connected through the bridge element.

18. The electronic device of claim 12, further comprising:
a heat dissipating structure disposed on the plurality of third chips.

19. The electronic device of claim 12, further comprising:
a thermal conductive material disposed between the at least two package units and the first interposer.

20. The electronic device of claim 19, wherein the thermal conductive material has an opening, and the electronic device further comprises:
a plurality of bonding elements disposed in the opening, wherein the first interposer and the at least two package units are electrically connected through the plurality of bonding elements.
